(19) United States
(12) Patent Application Publication
(10) Pub. No.: US 2026/0323997 A1
(43) Pub. Date: Oct. 15, 2026

(54) THIN FILM TRANSISTOR, DISPLAY SUBSTRATE, AND DISPLAY DEVICE

(71) Applicants: Beijing BOE Technology Development Co., Ltd., Beijing (CN); BOE Technology Group Co., Ltd., Beijing (CN)

(72) Inventors: Tianmin ZHOU, Beijing (CN); Jinchao ZHANG, Beijing (CN); Shunhang ZHANG, Beijing (CN); Lizhong WANG, Beijing (CN); Pengxia LIANG, Beijing (CN); Ce NING, Beijing (CN); Kun YANG, Beijing (CN)

(21) Appl. No.: 18/995,503

(22) PCT Filed: Nov. 28, 2023
(86) PCT No.: PCT/CN2023/134717

§ 371 Date: Jan. 16, 2025

(51) Int. Cl. H10D 30/67; H10D 86/40; H10D 86/60

(52) U.S. Cl. CPC H10D 30/673; H10D 30/6757; H10D 86/441; H10D 86/60

(57) ABSTRACT

Embodiments of the present disclosure provide a thin film transistor, a display substrate, and a display device. The thin film transistor includes: a base substrate; a first insulation layer on a side of the base substrate, the first insulation layer having a first concave portion; a first active layer on a side of the first insulation layer facing away from the base substrate, the first active layer including: a first portion, and a second portion on a side of the first portion, the second portion being in the first concave portion; a first metal layer on a same side of the base substrate as the first active layer, the first metal layer including: a first metal pattern, an orthographic projection of the first portion on the base substrate has an overlapping region with an orthographic projection of the first metal pattern on the base substrate.

### CROSS REFERENCE TO RELATED APPLICATION

The present disclosure is a national phase entry under 35 U.S. C § 371 of International Application No. PCT/CN2023/134717, filed on Nov. 28, 2023. The entire content of which is incorporated in the present disclosure by reference.

### TECHNICAL FIELD

This disclosure relates to the field of semiconductor technology, in particular to a thin film transistor, a display substrate, and a display device.

### BACKGROUND

With the rise of the concept of meta-universe, virtual reality technology (VR) headset products as a port device has attracted much attention, and now the display products with good effect in the market are usually 3000+PPI micro organic light-emitting display device (Micro OLED) products, but the high cost of Micro OLED products and the difficulty of the process make it difficult to popularize. Glass-based ultra-high resolution (Pixels Per Inch (PPI)) technology, which is expected to produce 2000PPI~3000PPI products while costing only one-tenth of silicon-based OLED products, is very attractive. Therefore the development of ultra-high PPI glass-based VR headset has huge market potential.

### SUMMARY

Embodiments of the present disclosure provide a thin film transistor, including:
a base substrate;
a first insulation layer, on a side of the base substrate and being provided with a first concave portion;
a first active layer, on a side of the first insulation layer facing away from the base substrate and including: a first portion, and a second portion on a side of the first portion; where the second portion is in the first concave portion;
a first metal layer, on a same side of the base substrate as the first active layer and including a first metal pattern; wherein an orthographic projection of the first portion on the base substrate has an overlapping region with an orthographic projection of the first metal pattern on the base substrate.

In possible embodiments, the thin film transistor further includes: a second insulation layer on a side of the first active layer facing away from the first insulation layer; and a first electrode on a side of the second insulation layer facing away from the first active layer;

Where the second insulation layer is provided with a first through hole, the first electrode is electrically connected to the second portion via the first through hole.

In possible embodiments, the first active layer further includes: a first connection portion between the first portion and the second portion, the first connection portion covers a portion of a side wall of the first concave portion;
the second insulation layer includes a first filling portion, an orthographic projection of the first filling portion on the base substrate has an overlapping region with an orthographic projection of the first concave portion on the base substrate, and the first filling portion covers the first connection portion.

In possible embodiments, the first insulation layer further includes: a second concave portion;
the first active layer further includes a third portion on an other side of the first portion; at least a portion of the third portion is in the second concave portion.

In possible embodiments, the first active layer further includes: a second connection portion between the first portion and the third portion, the second connection portion covers a portion of a side wall of the second concave portion;
the second insulation layer includes a second filling portion, an orthographic projection of the second filling portion on the base substrate has an overlapping region with an orthographic projection of the second concave portion on the base substrate, and the second filling portion covers the second connection portion.

In possible embodiments, the first active layer further includes: a fourth portion between the first portion and the first connection portion, and a fifth portion between the first portion and the second connection portion;
an orthographic projection of the fourth portion on the base substrate does not overlap the orthographic projection of the first metal pattern on the base substrate, and an orthographic projection of the fifth portion on the base substrate does not overlap the orthographic projection of the first metal pattern on the base substrate.

In possible embodiments, the first insulation layer further includes: a second concave portion;
at least a portion of the first portion is in the second concave portion.

In possible embodiments, the thin film transistor further includes: a second metal layer between the first insulation layer and the base substrate; the second concave portion is a second through hole penetrating through the first insulation layer;
the second metal layer includes a second metal pattern; at least a portion of the second metal pattern is in the second through hole, a portion of the third portion in the second through hole is electrically connected to the second metal pattern.

In possible embodiments, the second through hole includes: a first sub-through hole portion, and a second sub-through hole portion;
an orthographic projection of the first sub-through hole portion on the base substrate overlaps an orthographic projection of the second metal pattern on the base substrate, and an orthographic projection of the second sub-through hole portion on the base substrate is on a side of the first sub-through hole portion facing the first portion.

In possible embodiments, the second through hole includes: a first sub-through hole portion, and a second sub-through hole portion;
an orthographic projection of the first sub-through hole portion on the base substrate overlaps an orthographic projection of the second metal pattern on the base substrate, an orthographic projection of the second sub-through hole portion on the base substrate is on a side of the orthographic projection of the first sub-through hole portion on the base substrate facing away from the orthographic projection of the first portion on the base substrate.

In possible embodiments, the thin film transistor further includes: a second metal layer between the first insulation layer and the base substrate;
the second metal layer includes: a second metal pattern; the first active layer further includes: a third portion on an other side of the first portion;
the first metal layer further includes: a first adapter electrode; the third portion is electrically connected to the second metal pattern via the first adapter electrode.

In possible embodiments, an orthographic projection of the second metal pattern on the base substrate overlaps at least a portion of the orthographic projection of the first metal pattern on the base substrate.

In possible embodiments, the thin film transistor further includes: a second metal layer between the first insulation layer and the base substrate, and a third metal layer between the second metal layer and the base substrate;
the first active layer further includes: a third portion on an other side of the first portion;
the second metal layer includes: a second metal pattern; the third metal layer includes: a second adapter electrode; the third portion is electrically connected to the second metal pattern via the second adapter electrode.

In possible embodiments, at least a portion of an orthographic projection of the second metal pattern on the base substrate is on a side of an orthographic projection of the second adapter electrode on the base substrate facing away from the first portion.

In possible embodiments, at least a portion of an orthographic projection of the second metal pattern on the base substrate is on a side of an orthographic projection of the second adapter electrode on the base substrate close to the first portion.

In possible embodiments, the first insulation layer further includes: a second concave portion; the thin film transistor further includes: a second metal layer between the first insulation layer and the base substrate; the second concave portion is a second through hole penetrating through the first insulation layer;
the second metal layer includes: a second metal pattern, at least a portion of the second metal pattern is in the second through hole;
at least a portion of the first portion is in the second through hole, the portion of the first portion in the second through hole is electrically connected to the second metal pattern.

In possible embodiments, the second insulation layer includes: a first sub-insulation layer, and a second sub-insulation layer on a side of the first sub-insulation layer facing away from the first active layer;
the first metal layer is on a side of the first active layer facing away from the base substrate.

In possible embodiments, an orthographic projection of the first sub-insulation layer on the base substrate covers the orthographic projection of the first portion on the base substrate; the first sub-insulation layer includes a first filling portion.

In possible embodiments, an orthographic projection of the first sub-insulation layer on the base substrate covers at least a portion of the orthographic projection of the first portion on the base substrate, and the orthographic projection of the first sub-insulation layer on the base substrate does not overlap an orthographic projection of the second portion on the base substrate and does not overlap an orthographic projection of a third portion on the base substrate; the second sub-insulation layer includes the first filling portion.

In possible embodiments, the first concave portion has a depth in a direction perpendicular to the base substrate, and the depth is the same as a thickness of the first insulation layer in the direction perpendicular to the base substrate.

In possible embodiments, a depth e1 of the first through hole in a direction perpendicular to the base substrate satisfies a following relationship:

e2<e1≤e2+e3, wherein e2 indicates a thickness of the second insulation layer in a direction of the base substrate, and e3 indicates a thickness of the first insulation layer in the direction of the base substrate.

Embodiments of the present disclosure provide a display substrate, including a display area, and a non-display area at a periphery of the display area, wherein a first signal line, a second signal line, and at least one thin-film transistor in the embodiments of the present disclosure are provided in the display area.

In possible embodiments, the display substrate further includes: a fourth insulation layer on a side of a second insulation layer facing away from the first active layer, and a pixel electrode on a side of the fourth insulation layer facing away from the second insulation layer;
the fourth insulation layer is provided with a third through hole, the pixel electrode is electrically connected to the first electrode via the third through hole.

In possible embodiments, a center of an orthographic projection of the third through hole on the base substrate is on a side of a center of an orthographic projection of a first through hole on the base substrate facing away from the first portion;
the display substrate further includes: a lap electrode between the third insulation layer and the pixel electrode; the first electrode is electrically connected to the lap electrode via the third through hole, and the lap electrode is electrically connected to the pixel electrode.

In possible embodiments, a center of an orthographic projection of the third through hole on the base substrate coincides with a center of an orthographic projection of the first through hole on the base substrate;
the first electrode is electrically connected to the pixel electrode via the first through hole and the third through hole.

In possible embodiments, the first concave portion has an overlapping portion with an orthographic projection of the first through hole, the overlapping portion is on a side of the second portion facing away from the first signal line, a distance between the overlapping portion and the first signal line is greater than 0.75 μm.

In possible embodiments, the display substrate further includes a gate drive circuit in the non-display area; the gate drive circuit includes: a second active layer, a drive gate electrode on a side of the second active layer facing away from the base substrate, and a drive source-drain electrode on a side of the drive gate electrode facing away from the second active layer.

In possible embodiments, the drive source-drain electrode is in the second metal layer.

In possible embodiments, the drive gate electrode is in the third metal layer.

In possible embodiments, the drive source-drain electrode is in the first metal layer; and the drive gate electrode is in the second metal layer.

Embodiments of the present disclosure provide a display device, including the display substrate in the embodiments of the present disclosure.

### BRIEF DESCRIPTION OF FIGURES

FIG. 1 is a schematic diagram of a cross-sectional view of a thin film transistor provided by embodiments of the present disclosure.

FIG. 2A is a first one of cross-sectional schematic views of a display substrate provided by embodiments of the present disclosure.

FIG. 2B is one of top view schematic diagrams of a sub-pixel of a display substrate provided by embodiments of the present disclosure.

FIG. 2C is a schematic diagram of conductivization of a first active layer of a display substrate provided by embodiments of the present disclosure.

FIG. 2D is a schematic diagram of a display substrate provided by embodiments of the present disclosure when a first through hole is formed by etching.

FIG. 2E is a second one of cross-sectional schematic views of a display substrate provided by embodiments of the present disclosure.

FIG. 2F is a third one of cross-sectional schematic views of a display substrate provided by embodiments of the present disclosure.

FIG. 2G is one of top view schematic diagrams of a display substrate provided by embodiments of the present disclosure.

FIG. 3A is a fourth one of cross-sectional schematic views of a display substrate provided by embodiments of the present disclosure.

FIG. 3B is one of top view schematic diagrams of a sub-pixel of a display substrate provided by embodiments of the present disclosure.

FIG. 4 is a fifth one of cross-sectional schematic views of a display substrate provided by embodiments of the present disclosure.

FIG. 5 is a sixth one of cross-sectional schematic views of a display substrate provided by embodiments of the present disclosure.

FIG. 6 is a seventh one of cross-sectional schematic views of a display substrate provided by embodiments of the present disclosure.

FIG. 7A is an eighth one of cross-sectional schematic views of a display substrate provided by embodiments of the present disclosure.

FIG. 7B is a schematic diagram without setting a first concave portion provided by embodiments of the present disclosure.

FIG. 8 is a ninth one of cross-sectional schematic views of a display substrate provided by embodiments of the present disclosure.

FIG. 9 is a tenth one of cross-sectional schematic views of a display substrate provided by embodiments of the present disclosure.

FIG. 10A is an eleventh one of cross-sectional schematic views of a display substrate provided by embodiments of the present disclosure.

FIG. 10B is a top schematic view at a sub-pixel corresponding to FIG. 10A.

FIG. 11 is a twelfth one of cross-sectional schematic views of a display substrate provided by embodiments of the present disclosure.

FIG. 12A is a schematic diagram of a display substrate forming a second active layer provided by embodiments of the present disclosure.

FIG. 12B is a schematic diagram of a display substrate forming a drive gate electrode provided by embodiments of the present disclosure.

FIG. 12C is a schematic diagram of a display substrate forming a first insulation layer provided by embodiments of the present disclosure.

FIG. 12D is a schematic diagram of a display substrate etching the first insulation layer provided by embodiments of the present disclosure.

FIG. 12E is a schematic diagram in top view corresponding to FIG. 12D.

FIG. 12F is a schematic diagram of a display substrate forming a first metal pattern provided by embodiments of the present disclosure.

FIG. 12G is a schematic diagram in top view corresponding to FIG. 12F.

FIG. 12H is a schematic diagram of a display substrate forming a first electrode provided by embodiments of the present disclosure.

FIG. 12I is a schematic diagram of a display substrate forming a spacer provided by embodiments of the present disclosure.

### DETAILED DESCRIPTION

Embodiments of the present disclosure will be described in detail below in conjunction with the accompanying drawings. The embodiments may be implemented in a plurality of different forms. One of ordinary skill in the art to which it belongs can readily appreciate the fact that the manner and contents can be transformed into one or more forms without departing from the purpose of the present disclosure and its scope. Accordingly, the present disclosure should not be construed to be limited only to the contents recorded in the following embodiments. The embodiments and the features in the embodiments in the present disclosure may be combined with each other in any combination without conflict.

In the accompanying drawings, the size of one or more constituent elements, the thickness of a layer, or an area is sometimes exaggerated for clarity. Accordingly, one manner of the present disclosure is not necessarily limited to that size, and the shapes and sizes of the components in the accompanying drawings do not reflect true proportions. Furthermore, the accompanying drawings schematically illustrate desirable examples, and one manner of the present disclosure is not limited to the shapes or values, etc., shown in the accompanying drawings.

The ordinal terms, such as “first”, “second”, “third”, etc., in this specification are provided to avoid confusion of constituent elements, and are not intended to limit the quantity or the number. The “plurality of” in the present disclosure may include two or more.

In the specification, for the sake of convenience, words and phrases such as “middle”, “up”, “down”, “front”, “back”, “vertical”, “horizontal”, “top”, “bottom”, “inside”, “outside” are used to indicate the orientation or position relationship of the elements with reference to the accompanying drawings to explain the positional relationships of the constituent elements. This is only for the convenience of describing the specification and simplifying the description, and does not indicate or imply that the device or component referred to must have a specific orientation, be constructed and operated in a specific orientation. Therefore, it cannot be understood as a limitation on the disclosure. The positional relationship of the constituent elements is appropriately changed according to the direction of the described constituent elements. Therefore, not limited to the words and phrases described in the specification, it can be appropriately replaced according to the situation.

In the specification, the terms “mounted”, “connected”, and “coupled” are to be broadly construed unless otherwise expressly provided and limited. For example, the connection may be fixed, or removable, or integrally connected; it may be mechanically connected, or electrically connected; it may be directly connected, or indirectly connected through an intermediate member, or connected within two elements. To one of ordinary skill in the art, the meaning of the above terms in the present disclosure may be understood according to the situation.

For the purposes of the specification, “electrically connected” includes a situation in which the constituent elements are connected together by an element having some electrical function. There is no special limitation on the term “element having some electrical function” as long as the transmission of electrical signals between the connected constituent elements is possible. Examples of “element having some electrical function” include not only electrodes and wiring, but also switching elements such as transistors, resistors, inductors, capacitors, and other elements having one or more functions.

In the specification, a transistor is a component that includes at least three terminals: a gate electrode (gate), a drain electrode, and a source electrode. The transistor has a channel region between the drain electrode (drain electrode terminal, drain region, or drain electrode) and the source electrode (source electrode terminal, source region, or source electrode), and a current can flow through the drain electrode, the channel region, and the source electrode. In the present disclosure, the channel region is the region through which the current flows predominantly.

In the specification, in order to distinguish the two electrodes of the transistor other than the gate electrode, one of the electrodes is referred to as a first electrode and the other electrode is referred to as a second electrode, and the first electrode may be a source electrode or a drain electrode, and the second electrode may be a drain electrode or a source electrode. Alternatively, the gate electrode of the transistor may be referred to as the control electrode.

The functions of the “source electrode” and the “drain electrode” are sometimes switched with each other when transistors of opposite polarity are used, or when the direction of the current changes in circuit operation. Therefore, in the specification, the “source electrode” and the “drain electrode” are interchangeable.

In the specification, “parallel” refers to a state in which an angle formed by two straight lines is −10° or more and 10° or less, and therefore, a state in which the angle is −5° or more and 5° or less can be included. In addition, “perpendicular” refers to a state in which an angle formed by two straight lines is 80° or more and 100° or less, and therefore, a state in which the angle is 85° or more and 95° or less can be included.

In the specification, a triangle, rectangle, trapezoid, pentagon, or hexagon, etc., is not strictly defined, but can be approximate to triangle, rectangle, trapezoid, pentagon, or hexagon, etc., and there can be some small deformations due to tolerance, such as a leading angle, an arc edge, and deformations.

In the specification, “film” and “layer” can be interchangeable. For example, the term “conduction layer” can be changed to “conduction film”. Similarly, “insulation film” can be replaced with “insulation layer”.

In the specification, the terms “about” and “approximately” refer to a situation in which process and measurement errors are permissible without strictly limiting the boundaries. In this specification, “approximately the same” can be a case where the difference in index value is less than 10%.

Ultra-high PPI is currently an optimal choice for a liquid crystal display (LCD) technology, because in a LCD display structure, a pixel area circuit has only one switch transistor (Thin Film Transistor (TFT)), which is very conducive to the realization of high PPI, but the transmittance of the LCD is low, and backplane process schemes with a high aperture ratio need to be developed, especially when the PPI reaches 2000 or more, a variety of line widths, line spacing and through hole size have reached the limit of the manufacturing capacity of the display device, the area of the opening area is dramatically compressed, which can cause a large impact on the performance of the thin film transistor, for example, a reduction in the channel of the thin film transistor and a problem of negative bias in the threshold voltage.

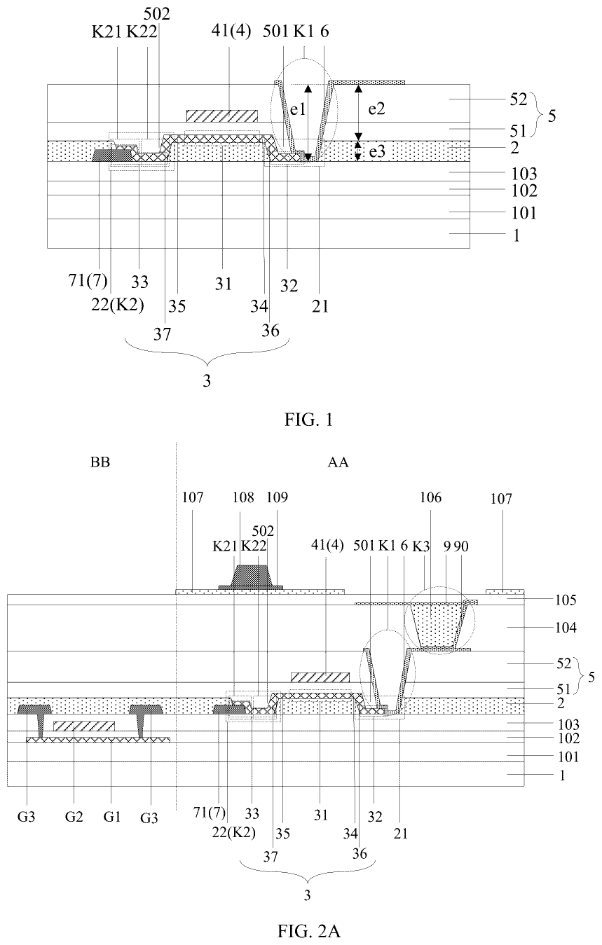

In view of this, embodiments of the present disclosure provide a thin film transistor, as shown in FIG. 1, including:
a base substrate 1;
a first insulation layer 2, on a side of the base substrate 1, the first insulation layer 2 having a first concave portion 21;
a first active layer 3, on a side of the first insulation layer 2 facing away from the base substrate 1, the first active layer 3 including: a first portion 31, and a second portion 32 on a side of the first portion 31; the second portion 32 being in the first concave portion 21;
a first metal layer 4, on a same side of the base substrate 1 as the first active layer 3, the first metal layer 4 including: a first metal pattern 41, where an orthographic projection of the first portion 31 on the base substrate 1 has an overlapping region with an orthographic projection of the first metal pattern 41 on the base substrate 1. Specifically, a region in the first active layer 3 that overlaps with the orthographic projection of the first metal pattern 41 can be taken as the first portion 31; specifically, the orthographic projection of the second portion 32 on the base substrate 1 does not overlap the orthographic projection of the first metal pattern 41 on the base substrate 1.

In embodiments of the present disclosure, the first insulation layer 2 has a first concave portion 21, and the second portion 32 of the first active layer 3 is in the first concave portion 21, which can cause the first portion 31 and the second portion 32 of the first active layer 3 to form a bending structure in a direction perpendicular to the base substrate 1, so that the first portion 31 and the second portion 32 are delaminated, and the region of lateral climb is formed between the first portion 31 and the second portion 32, and when the second portion 32 is conducted by the conductive process, the degree of diffusion of the conductive ions to the first portion 31 can be reduced, improving the problem that the conductive process reduces the channel length due to the diffusion of the ions, enhancing the characteristics of the short-channel device, and thus improving the current problem that the channel of the thin-film transistor is reduced and the threshold voltage is negatively biased due to the increase of the resolution and transmittance so that the performance of the thin-film transistor is affected to a large extent.

In possible embodiments, the first concave portion 21 can be recessed by a surface of the first insulation layer 2 facing away from the base substrate 1 towards a side of the base substrate 1; in possible embodiments, a depth of the concave portion may be less than a thickness of the first insulation layer 2 in a direction perpendicular to the base substrate 1; in another possible embodiment, the depth of the concave portion may be equal to the thickness of the first insulation layer 2 in the direction perpendicular to the base substrate 1, i.e., the first concave portion 21 may be a through hole penetrating through the first insulation layer 2.

In possible embodiments, the first metal layer 4 may be a gate metal layer, the first metal pattern 41 may be a gate electrode, and the first portion 31, which is overlapped with the projection of the first metal pattern 41, may be a channel region; in possible embodiments, the second portion 32 may be a drain region of the thin film transistor; in another possible embodiment, the second portion 32 may also be a source region of the thin film transistor.

In possible embodiments, the thin film transistor provided by embodiments of the present disclosure may be a thin film transistor in a display panel. In another possible embodiment, the thin film transistor provided by the embodiments of the present disclosure, may also be a thin film transistor in a non-display panel, for example, the thin film transistor may be a thin film transistor in a photosensitive structure, for example, the thin film transistor may be a thin film transistor in a light detecting assembly or a thin film transistor in a photovoltaic assembly, and the like.

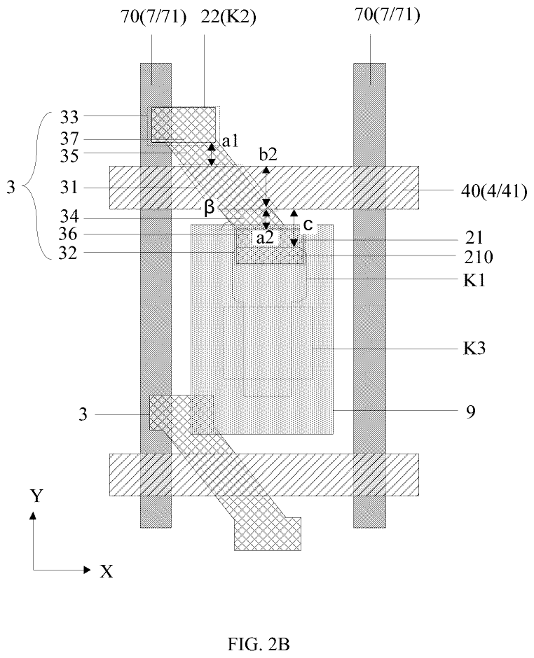

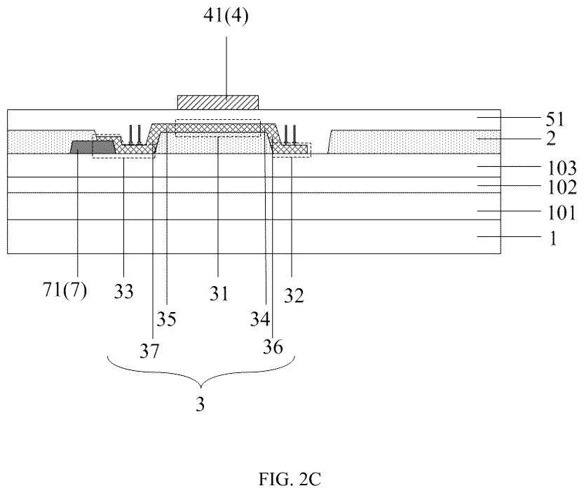

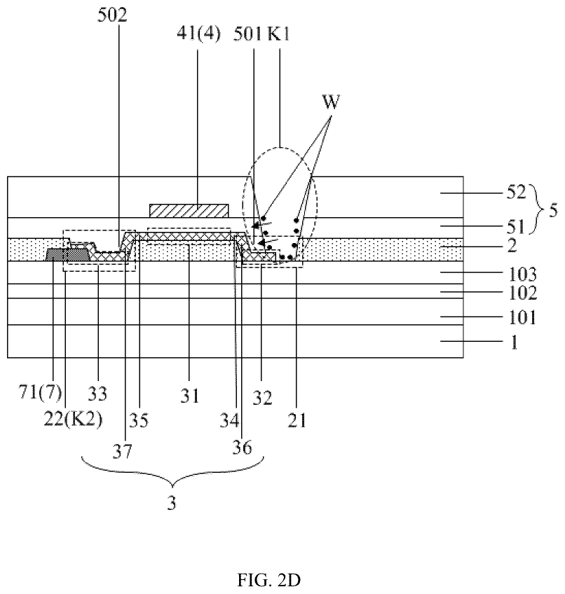

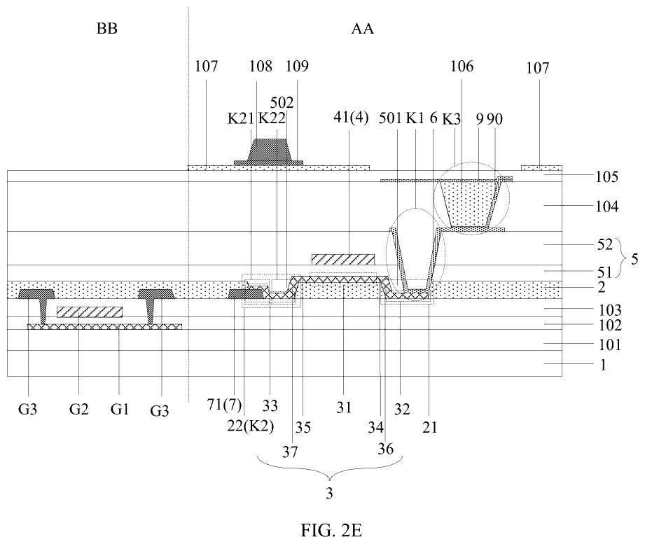

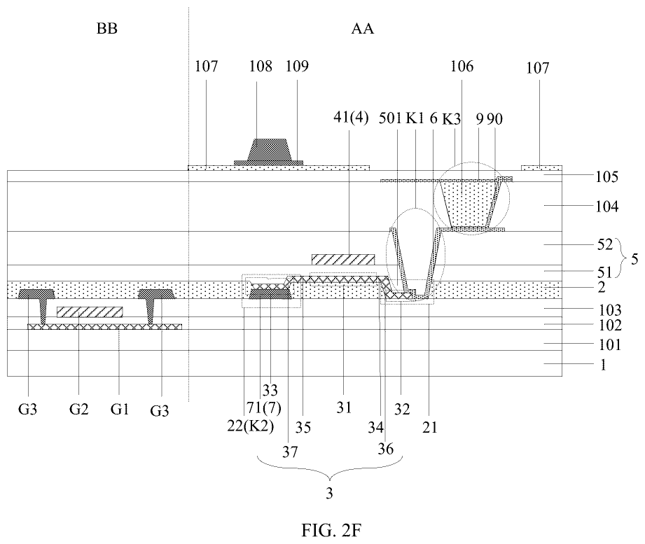

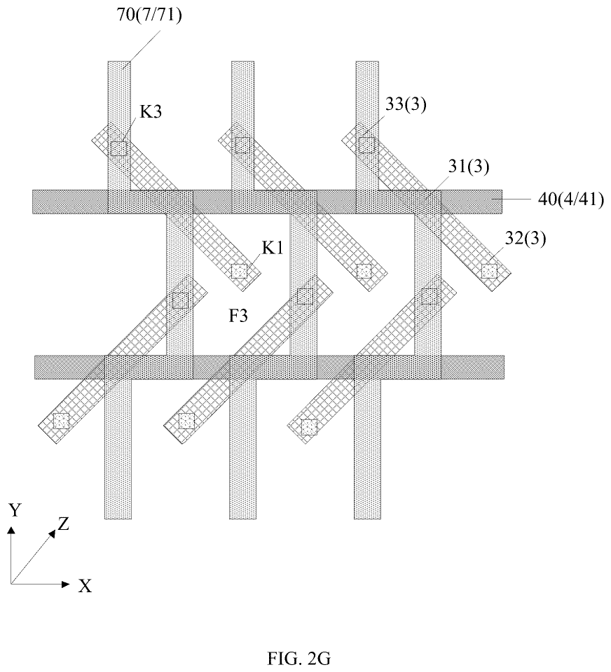

In possible embodiments, referring to FIGS. 2A and 2B, the display panel may include a display area AA, and a non-display area BB at the periphery of the display area AA, and the thin-film transistor may be a thin-film transistor in the display area AA, and specifically may be a thin-film transistor in a pixel circuit(s) in the display area AA.

In possible embodiments, as shown in FIGS. 2A and 2B, the thin-film transistor further includes: a second insulation layer 5 on the side of the first active layer 3 facing away from the first insulation layer 2, and a first electrode 6 on the side of the second insulation layer 5 facing away from the first active layer 3; the second insulation layer 5 has a first through hole K1, and the first electrode 6 is electrically connected to the second portion 32 via the first through hole K1.

In possible embodiments, as shown in conjunction with FIG. 2A, the second portion 32 may be only a portion covering the first concave portion 21, and the first electrode 6 may be partially in contact with the second portion 32 and partially in contact with the bottom of the first concave portion 21.

In possible embodiments, as shown in conjunction with FIG. 2E, the second portion 32 may cover the entirety of the first concave portion 21, the first electrode 6 is in contact with a surface on the side of the second portion 32 facing away from the base substrate 1.

In possible embodiments, as shown in conjunction with FIGS. 2A and 2B, the orthographic projection of the first through hole K1 on the base substrate 1 overlaps the orthographic projection of the first concave portion 21 on the base substrate 1, and the area of the overlapping region is not less than 25% of the area of the orthographic projection of the first concave portion 21, so as to ensure the lap resistance.

In possible embodiments, as shown in conjunction with FIGS. 2A and 2B, a depth e1 of the first through hole in the direction perpendicular to the base substrate satisfies the following relationship:

e2<e1≤e2+e3, where e2 indicates a thickness of the second insulation layer 5 in a direction of the base substrate, and e3 indicates a thickness of the first insulation layer 2 in the direction of the base substrate 1. That is, the first through hole K1 simultaneously etches the second sub-insulation layer 52, the first sub-insulation layer 51, and the first insulation layer 2, and the area of the orthographic projection of the first through hole K1 on the base substrate 1 is greater than the area of the orthographic projection of the first concave portion 21 on the base substrate 1. However, it is necessary to ensure that the depth of the etching of the first through hole K1 is greater than the sum of the thicknesses of the second sub-insulation layer 52 and the first sub-insulation layer 51, and is less than or equal to the sum of the thicknesses of the second sub-insulation layer 52, the first sub-insulation layer 51, and the first insulation layer 2, to avoid the problem of fracture of the first electrode 6 climbing due to over-etching of the third insulation layer 103 to form a segment difference.

In possible embodiments, the first electrode 6 may be a drain electrode of the thin film transistor. In possible embodiments, the material of the first electrode 6 may be a metal or a transparent metal oxide, and the material of the first electrode 6 may include: indium tin oxide (ITO), zinc oxide (ZnO), indium zinc oxide (IZO), or a conductive oxide similar thereto.

In possible embodiments, as shown in FIGS. 2A and 2B, the first active layer 3 further includes: a first connection portion 36 between the first portion 31 and the second portion 32, the first connection portion 36 covers a portion of a side wall of the first concave portion 21, specifically, the first connection portion 36 covers a side wall of the first concave portion 21 facing the first portion 31; and the second insulation layer 5 includes a first filling portion 501, an orthographic projection of the first filling portion 501 on the base substrate 1 has an overlapping region with an orthographic projection of the first concave portion 21 on the base substrate 1, and the first filling portion 501 covers the first connection portion 36.

In embodiments of the present disclosure, the first active layer 3 further includes a first connection portion 36 covering a portion of the side wall of the first concave portion 21, and a first filling portion 501 covering the first connection portion 36, where the first connection portion 36 may form a lateral climbing region between the first portion 31 and the second portion 32, and during the conductive of the second portion 32 by a conductive process (as shown in FIG. 2C, where the thick arrows indicate a conductive ion injection), the first connection portion 36 can reduce the diffusion of the conductive ions to the first portion 31, improving the problem that the conductive process reduces the channel length, and improving the characteristics of the short-channel device; the first filling portion 501 is covered with the first connection portion 36, and when etching to form the first through hole K1, the first filling portion 501 can block the diffusion of dry-etching by-products (e.g., as shown in FIG. 2D, the black ball indicates dry-etching products), which can further enhance the characteristics of the short channel device.

In possible embodiments, as shown in conjunction with FIG. 1, FIG. 2A, or FIG. 2B, the first insulation layer 2 further includes: a second concave portion 22; and the first active layer 3 further includes: a third portion 33 on the other side of the first portion 31; and at least a portion of the third portion 33 is in the second concave portion 22.

In possible embodiments, the second concave portion 22 can be recessed by a surface of the first insulation layer 2 facing away from the base substrate 1 towards a side of the base substrate 1; in possible embodiments, a depth of the second concave portion 22 may be less than a thickness of the first insulation layer 2 in the direction perpendicular to the base substrate 1; in another possible embodiment, the depth of the second concave portion 22 may be the same as the thickness of the first insulation layer 2 in the direction perpendicular to the base substrate 1, i.e., the second concave portion 22 may also be a through hole penetrating through the first insulation layer 2.

In possible embodiments, the depth of the second concave portion 22 can be the same as the depth of the first concave portion 21, for example, the depths of the second concave portion 22 and the first concave portion 21 can both be the same as the thickness of the first insulation layer 2 in the direction perpendicular to the base substrate 1; in another possible embodiment, the depth of the second concave portion 22 can also be less than the depth of the first concave portion 21.

In possible embodiments, when the second portion 32 is a drain area of the thin film transistor, the third portion 33 may be a source area of the thin film transistor; in another possible embodiment, when the second portion 32 is a source area of the thin film transistor, the third portion 33 may be a drain area of the thin film transistor.

In possible embodiments, as shown in conjunction with FIG. 1, FIG. 2A, or FIG. 2B, the first active layer 3 further includes: a second connection portion 37 between the first portion 31 and the third portion 33, the second connection portion 37 covers a portion of a side wall of the second concave portion 22, specifically, the second connection portion 37 covers a side wall of the second concave portion 22 toward the first portion 31; and the second insulation layer 5 includes a second filling portion 502. An orthographic projection of the second filling portion 502 on the base substrate 1 has an overlapping region with an orthographic projection of the second concave portion 22 on the base substrate 1, and the second filling portion 502 covers the second connection portion 37.

In possible embodiments, as shown in conjunction with FIG. 1, FIG. 2A, or FIG. 2B, the first active layer 3 further includes: a fourth portion 34 between the first portion 31 and the first connection portion 36, and a fifth portion 35 between the first portion 31 and the second connection portion 37; an orthographic projection of the fourth portion 34on the base substrate 1 does not overlap an orthographic projection of the first metal pattern 41 on the base substrate 1, and an orthographic projection of the fifth portion 35 on the base substrate 1 does not overlap the orthographic projection of the first metal pattern 41 on the base substrate.

In possible embodiments, in the first active layer 3, the first portion 31 may be a channel region, the second portion 32 and the third portion 33 may be a conductorization region, the fourth portion 34, the fifth portion 35, the first connection portion 36 and the second connection portion 37 may be a transition region, i.e., an un-conductorization region; the fourth portion 34, the fifth portion 35, the first connection portion 36 and the second connection portion 37 may all be a structure that blocks the diffusion of ions during the conductorization process. In embodiments of the present disclosure, compared with the related art, the first connection portion 36 and the second connection portion 37 are used to increase the length of the transition region, which reduces the impact on the channel during the conductive process.

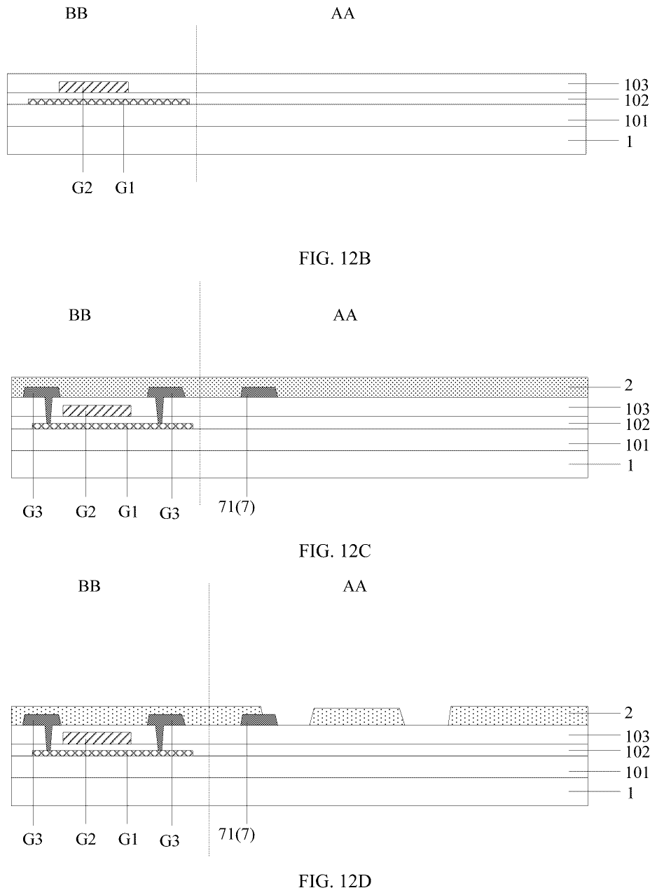

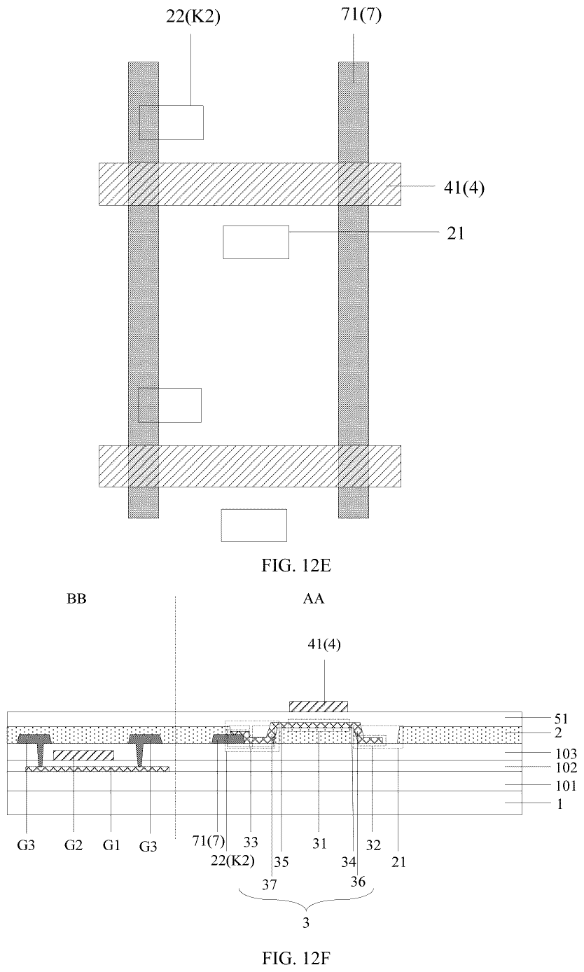

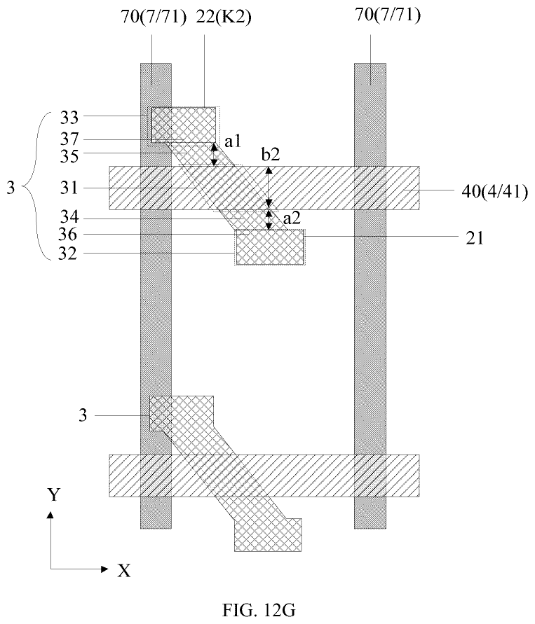

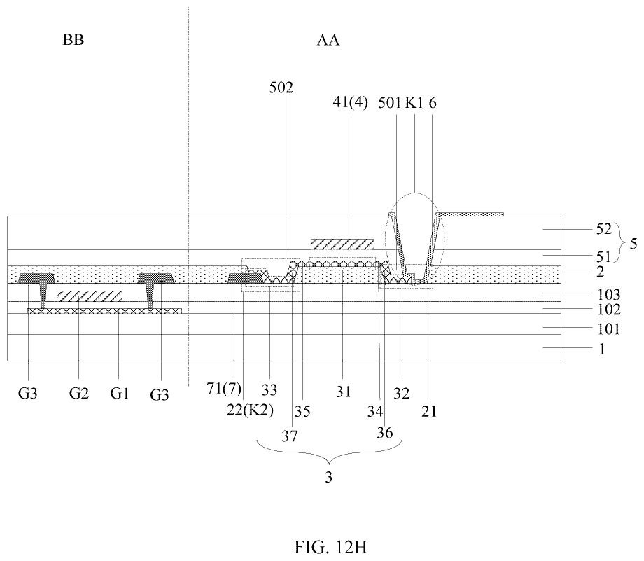

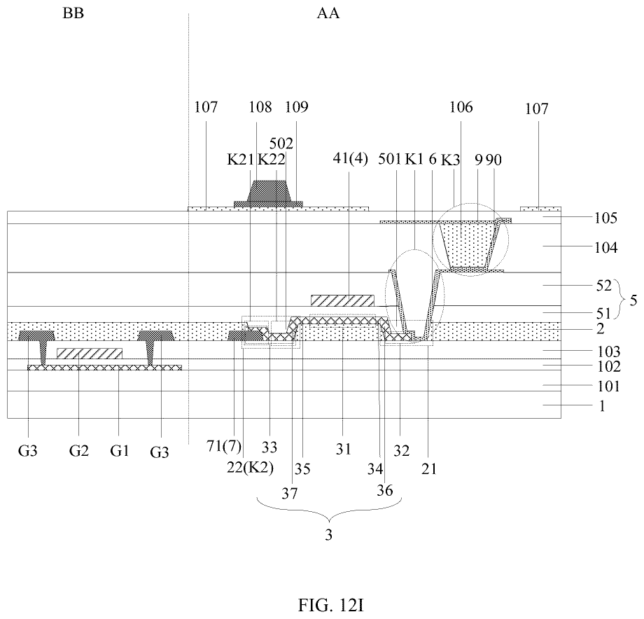

In possible embodiments, as shown in conjunction with FIG. 12G, the width b1 of the un-conductorization region in the second direction Y, and the width b2 of the first signal line 40 in the second direction Y satisfy: b2×30%<b1<b2×75%, where b1=a1+a2. In this way, the aperture ratio of the display panel can be improved while improving the effect of the short channel.

In possible embodiments, as shown in conjunction with FIG. 1, FIG. 2A, or FIG. 2B, the thin film transistor further includes: a second metal layer 7 between the first insulation layer 2 and the base substrate 1; the second concave portion 22 is a second through hole K2 penetrating through the first insulation layer 2; the second metal layer 7 includes: a second metal pattern 71, at least a portion of the second metal pattern 71 is in the second through hole K2, and a portion of the third portion 33 in the second through hole K2 is electrically connected to the second metal pattern 71. In the embodiments of the present disclosure, the second metal pattern 71 is between the first insulation layer 2 and the base substrate 1, and the second metal pattern 71 is electrically connected to the third portion 33. Compared to the conventional technology in which the number of dielectric layers between the second metal pattern 71 and the first electrode 6 is relatively small, the embodiments of the present disclosure can increase the number of dielectric layers between the second metal pattern 71 and the first electrode 6, and increase the distance between the second metal pattern 71 and the first electrode 6 in the direction perpendicular to the base substrate 1, thereby reducing the parasitic capacitance between the second metal pattern 71 and the first electrode 6, and thereby reducing the signal crosstalk problem.

Compared to a conventional thin film transistor, in the embodiments of the present disclosure, the second metal pattern 71 electrically connected to the third portion 33 is placed downwardly, and the second metal pattern 71 is conducted with the third portion 33 via the second through hole K2; furthermore, during forming the second through hole K2 that conducts the second metal pattern 71 and the third portion 33, the first concave portion 21 is formed concurrently via the same mask plate in a single mask patterning process, so as to form the second through hole K2 that conducts the third portion 33 and the second metal pattern 71 in the single mask patterning process, and to form the first concave portion 21 that makes the second portion 32 depressed concurrently, so as to improve the short channel problem and enhance the characteristics of the short channel device without adding a new mask patterning process.

In possible embodiments, the second metal pattern 71 may be a source electrode of the thin film transistor. In possible embodiments, the material of the second metal pattern 71 may be a metal.

In possible embodiments, as shown in conjunction with FIG. 2B, the display panel may include a first signal line 40 (e.g., a gate line) extending along a first direction X, and a second signal line 70 (e.g., a data line) extending along a second direction Y; a portion of the first signal line 40 may be used as a first metal pattern 41; and a portion of the second signal line 70 may be used as a second metal pattern 71.

In possible embodiments, as shown in conjunction with FIG. 1 or FIG. 2A, the second through hole K2 includes: a first sub-through hole portion K21, and a second sub-through hole portion K22. An orthographic projection of the first sub-through hole portion K21 on the base substrate 1 overlaps an orthographic projection of the second metal pattern 71 on the base substrate 1. An orthographic projection of the second sub-through hole portion K22 on the base substrate 1 is on a side of the orthographic projection of the first sub-through hole portion K21 on the base substrate 1 toward an orthographic projection of the first portion 31 on the base substrate 1. In the embodiments of the present disclosure, the second through hole K2 is partially lapped in the second metal pattern 71 and partially in a region other than the second metal pattern 71, i.e., a half-lap design is adopted, in which way, the size of the second through hole K2 can be reduced, which is conducive to increasing the transmittance rate of the display panel.

In possible embodiments, as shown in conjunction with FIG. 2F, the second through hole K2 may also be all in the region where the second metal pattern 71 is located, and the third portion 33 is all in contact with the second metal pattern 71, i.e., the third portion 33 is connected to the second metal pattern 71 in a full-lap manner.

As shown in conjunction with FIGS. 2A and 2B, in the high-resolution display panel, the data line 70, which is multiplexed to be the second metal pattern 71, is relatively thin, and the second through hole K2 is sized in the first direction X. However, when the third portion 33 is formed within the second through hole K2, due to the presence of an automatic compensation mechanism, the third portion 33 can be compensated into the shape of the second through hole K2 via the automatic compensation mechanism to ensure that the third portion 33 has a larger lap area with the second metal pattern 71, reducing the lap resistance and allowing for greater process fluctuations to be accepted.

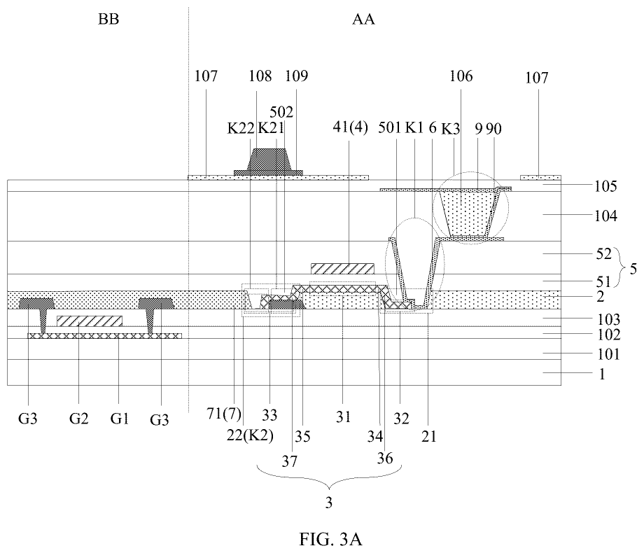

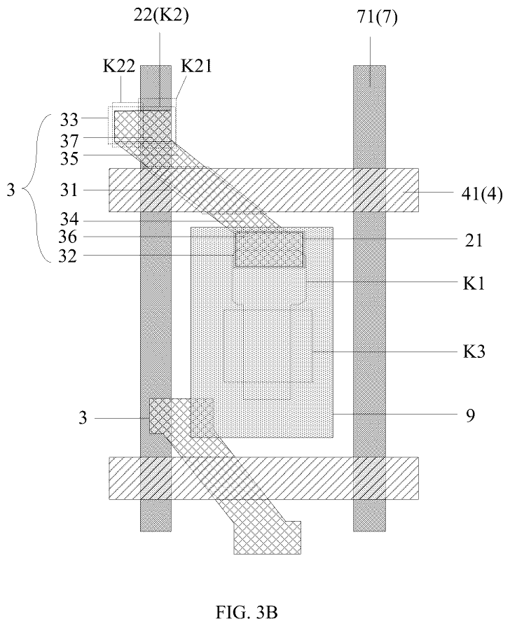

In possible embodiments, as shown in FIGS. 3A and 3B, the second through hole K2 includes: a first sub-through hole portion K21, and a second sub-through hole portion K22. An orthographic projection of the first sub-through hole portion K21 on the base substrate 1 overlaps an orthographic projection of the second metal pattern 71 on the base substrate 1. An orthographic projection of the second sub-through hole portion K22 on the base substrate 1 is on a side of the orthographic projection of the first sub-through hole portion K21 on the base substrate 1 facing away from an orthographic projection of the first portion 31 on the base substrate 1. In the embodiments of the present disclosure, the lap position of the second through hole K2 and the second metal pattern 71 can be adjusted, i.e., the second through hole K2 can be lapped with the second metal pattern 71 through the side of the third portion 33 close to the first portion 31, and the contact position and the contact area of the lap can be changed, which can increase the diagonal length of the channel.

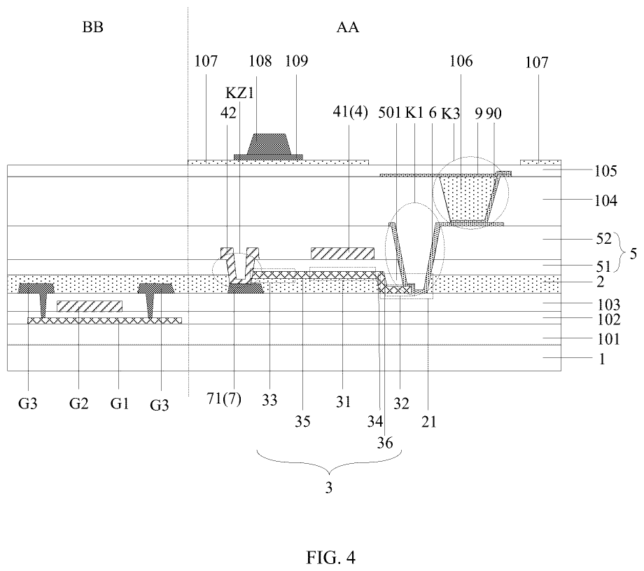

Specifically, the first active layer 3 and the second metal pattern 71 may be electrically connected in various ways. For example, the first active layer 3 and the second metal pattern 71 may be electrically via a first adapter electrode of the first metal layer 4. Specifically, referring to FIG. 4, the thin film transistor further includes: a second metal layer 7 between the first insulation layer 2 and the base substrate 1.

The second metal layer 7 includes: a second metal pattern 71; and the first active layer 3 further includes: a third portion 33 on the other side of the first portion 31.

The first metal layer 4 further includes: a first adapter electrode 42; the third portion 33 is electrically connected to the second metal pattern 71 via the first adapter electrode 42.

In the embodiments of the present disclosure, the first metal layer 4 further includes: a first adapter electrode 42; the first adapter electrode 42 is electrically connected to the second metal pattern 71 via the first adapter electrode 42, which can avoid the formation of a down-lap between the third portion 33 and the second metal pattern 71, and due to the adoption of the ion injection scheme, the conductorized layer usually concentrates on the surface layer of the third portion 33, and the down-lap between the third portion 33 and the second metal pattern 71 has a large contact resistance, which is prone to lead to the problem of low open-state current.

Specifically, as shown in conjunction with FIG. 4, the second insulation layer 5 includes: a first sub-insulation layer 51, and a second sub-insulation layer 52 on the side of the first sub-insulation layer 51 facing away from the first active layer 3; the thin film transistor further includes: a first adapter hole KZ1 penetrating through the first sub-insulation layer 51 and the first insulation layer 2, and the third portion 33 can be electrically connected to the second metal pattern 71 through the first adapter electrode 42, specifically at the first adapter hole KZ1.

Specifically, as shown in conjunction with FIG. 4, the first adapter electrode 42 may include a portion at the bottom of the first adapter hole KZ1, a portion covering the side wall of the first adapter hole KZ1, and a portion that extends outwardly to the first sub-insulation layer 51 facing away from the surface of the first insulation layer. The first adapter electrode 42 at the bottom of the first adapter hole KZ1 is in contact with the second metal pattern 71, the first adapter electrode 42 covering the side wall of the first adapter hole KZ1 is in contact with the side wall of the third portion 33, thereby realizing electrical connection between the third portion 33 and the second metal pattern 71.

In possible embodiments, referring to FIG. 4, the orthographic projection of the second metal pattern 71 on the base substrate 1 does not overlap the orthographic projection of the first metal pattern 41 on the base substrate 1.

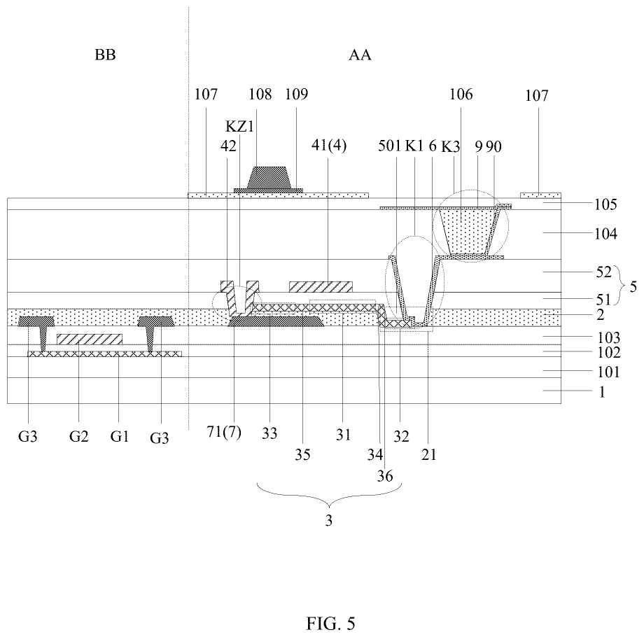

In possible embodiments, referring to FIG. 5, the orthographic projection of the second metal pattern 71 on the base substrate 1 overlaps at least a portion of the orthographic projection of the first metal pattern 41 on the base substrate 1. In this way, a light shielding function on the channel area of the thin film transistor can be provided to increase the light stability of the thin film transistor.

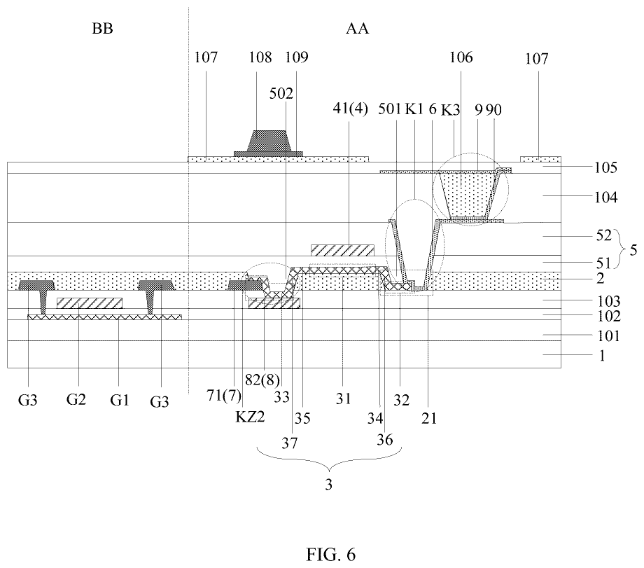

In possible embodiments, the first active layer 3 and the second metal pattern 71 may also be electrically connected via an adapter electrode of the third metal layer as shown. Specifically, referring to FIG. 6, the thin film transistor further includes: a second metal layer 7 between the first insulation layer 2 and the base substrate 1, and a third metal layer 8 between the second metal layer 7 and the base substrate 1.

The first active layer 3 further includes: a third portion 33 on the other side of the first portion 31.

The second metal layer 7 includes: a second metal pattern 71; the third metal layer 8 includes: a second adapter electrode 82; the third portion 33 is electrically connected to the second metal pattern 71 via the second adapter electrode 82.

In the embodiments of the present disclosure, the thin film transistor also includes the second adapter electrode 82, and the third portion 33 is electrically connected to the second metal pattern 71 via the second adapter electrode 82, which can avoid some problems brought by the under-lap, such as a large contact resistance, and at the same time, the second adapter electrode 82 can be borrowed to shield the through hole at the position (i.e., the through hole that conducts the third portion 33 with the second metal pattern 71, such as the second adapter hole KZ2), which is conducive to reducing the light leakage from the second adapter hole KZ2 and improving the contrast.

Specifically, a third insulation layer 103 is further provided between the first insulation layer 2 and the third metal layer 8, and the thin film transistor includes: a second adapter hole KZ2 penetrating through the first insulation layer 2 and the third insulation layer 103. Specifically, the third portion 33 can be electrically connected to the second metal pattern 71 via the second adapter electrode 82, at the second adapter hole KZ2.

Specifically, as shown in conjunction with FIG. 6, the third portion 33 can include a portion at the bottom of the second adapter hole KZ2, and a portion that extends outwardly to the surface of the side of the second metal pattern 71 facing away from the third insulation layer 103. The third portion 33 at the bottom of the second adapter hole KZ2 is in contact with the second adapter electrode 82, the third portion 33 that extends outwardly to the surface of the side of the second metal pattern 71 facing away from the third insulation layer 103 is in contact with the second metal pattern 71, thereby realizing electrical connection between the third portion 33 and the second metal pattern 71.

In possible embodiments, referring to FIG. 6, at least a portion of the orthographic projection of the second metal pattern 71 on the base substrate 1 is on a side of the orthographic projection of the second adapter electrode 82 on the base substrate 1 facing away from the first portion 31.

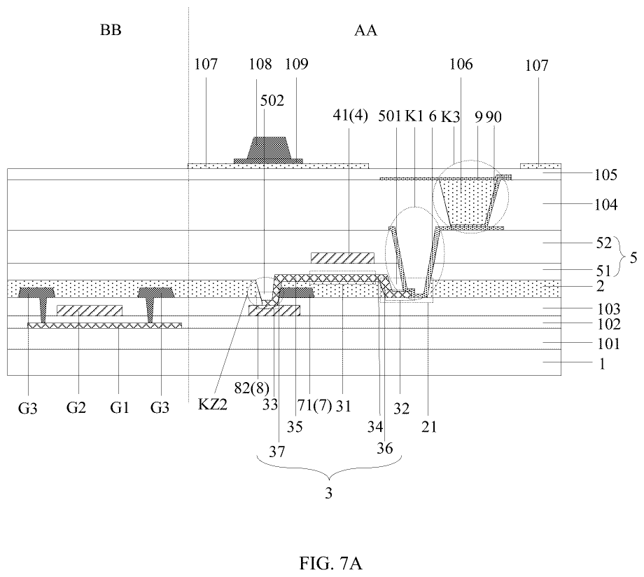

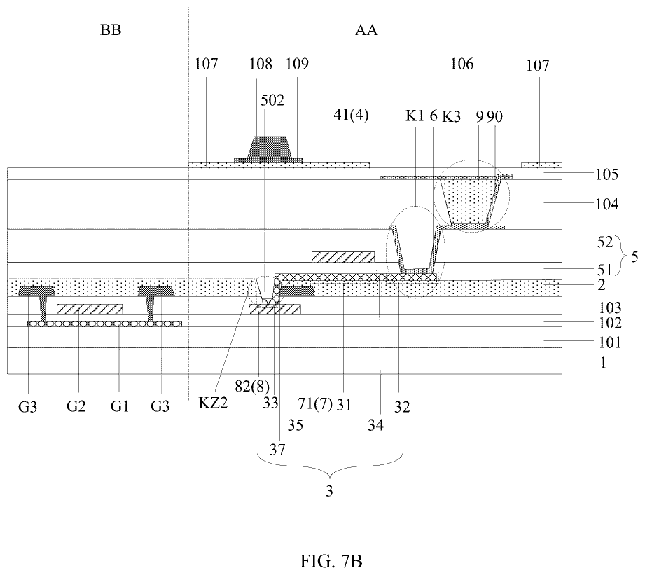

In possible embodiments, referring to FIG. 7A, at least a portion of the orthographic projection of the second metal pattern 71 on the base substrate 1 is on a side of the orthographic projection of the second adapter electrode 82 on the base substrate 1 close to the first portion 31. In this way, some problems brought about by the under-lap, such as a large contact resistance, can be avoided, and at the same time, the second adapter electrode 82 can be used to shade the through hole at the position (i.e., the through hole that conducts the third portion 33 with the second metal pattern 71, such as the second adapter hole KZ2), which is helpful for reducing the light leakage of the second adapter hole KZ2 and increasing the contrast.

In possible embodiments, referring to FIG. 7B, the first insulation layer 2 may also not be provided with the first concave portion 21, and the second portion 32 and the first portion 31 may also be in substantially the same plane. In this way, some problems brought about by the under-lap can be avoided, such as a large contact resistance, and at the same time, the second adapter electrode 82 can be used to shade the through hole (i.e., the through hole that conducts the third portion 33 with the second metal pattern 71, such as the second adapter hole KZ2) at the position, which is conducive to reducing the light leakage of the second adapter hole KZ2 and enhancing the contrast ratio; at the same time, compared to FIG. 7A, in the embodiments of the present disclosure, the first concave portion 21 and the second concave portion 22 may not be provided, which can reduce a mask patterning process.

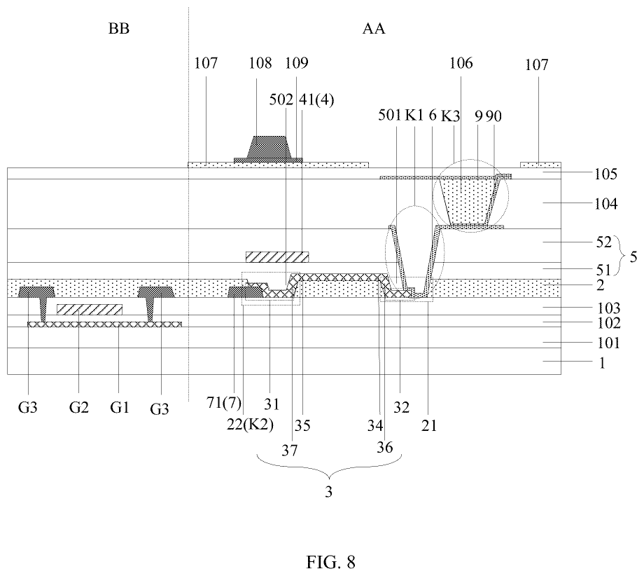

In possible embodiments, as shown in FIG. 8, the first insulation layer 2 further includes: a second concave portion 22; the thin film transistor further includes: a second metal layer 7 between the first insulation layer 2 and the base substrate 1; and the second concave portion 22 is a second through hole K2 penetrating through the first insulation layer 2.

The second metal layer 7 includes: a second metal pattern 71. At least a portion of the second metal pattern 71 is in the second through hole K2.

At least a portion of the first portion 31 is in the second concave portion 22, and the portion of the first portion 31 in the second through hole K2 is electrically connected to the second metal pattern 71.

In the embodiments of the present disclosure, at least a portion of the second through hole K2 is in a region where an orthographic projection of the second metal pattern 71 overlaps with an orthographic projection of the first metal pattern 41, forming a similar vertical channel structure to further reduce the size of the thin film transistor, reduce the area occupied by the thin film transistor in the display panel, and thereby enhance the aperture ratio of the display panel.

In possible embodiments, referring to FIG. 8, the orthographic projection of the second through hole K2 on the base substrate 1 has an overlapping region with the orthographic projection of the gate electrode (e.g., the first metal pattern 41) on the base substrate 1, and the orthographic projection of the gate electrode (e.g., the first metal pattern 41) on the base substrate 1 covers the orthographic projection of the second through hole K2 on the base substrate 1, which ensures that the portion of the first active layer 3 within the second through hole K2 can be driven by the gate electrode (e.g., the first metal pattern 41).

In possible embodiments, as shown in conjunction with FIG. 1, FIG. 2A-FIG. 2G, FIG. 3A-FIG. 3B, FIG. 4, FIG. 5, FIG. 6, FIG. 7A-FIG. 7B, and FIG. 8, the second insulation layer 5 includes: a first sub-insulation layer 51, and a second sub-insulation layer 52 on the side of the first sub-insulation layer 51 facing away from the first active layer 3; and the first metal layer 4 is on the side of the first active layer 3 facing away from the base substrate 1. In the embodiments of the present disclosure, the thin film transistor is a top-gate type thin film transistor. The top-gate type thin film transistor in the embodiments of the present disclosure can be conductive to improving an aperture ratio of the pixel compared to the conventional double-gate type thin film transistor.

In possible embodiments, as shown in conjunction with FIG. 1, FIG. 2A-FIG. 2G, FIG. 3A-FIG. 3B, FIG. 4, FIG. 5, FIG. 6, FIG. 7A-FIG. 7B, and FIG. 8, the orthographic projection of the first sub-insulation layer 51 on the base substrate covers the orthographic projection of the first portion 31 on the base substrate 1; and the first sub-insulation layer 51 includes a first filling portion 501.

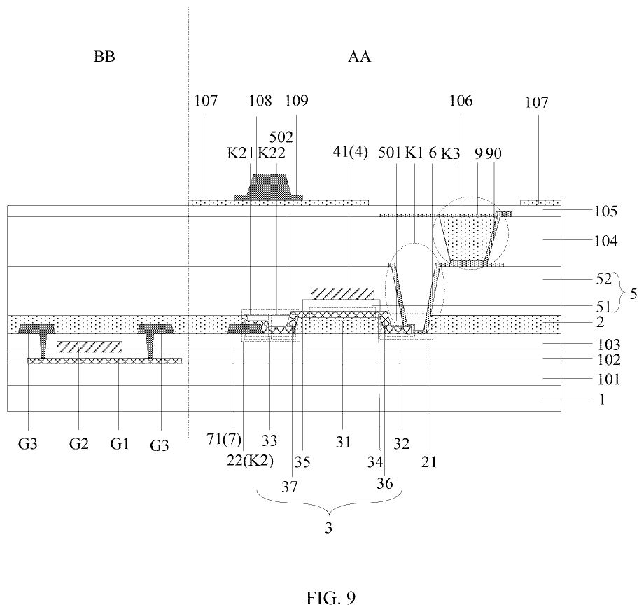

In possible embodiments, see FIG. 9, the orthographic projection of the first sub-insulation layer 51 on the base substrate 1 covers at least a portion of the orthographic projection of the first portion 31 on the base substrate 1, and the orthographic projection of the first sub-insulation layer 51 on the base substrate 1 does not overlap the orthographic projection of the second portion 32 on the base substrate 1, and does not overlap the orthographic projection of the third portion 33 on the base substrate 1; and the second sub-insulation layer 52 includes the first filling portion 501. In the embodiments of the present disclosure, the first sub-insulation layer 51 can be etched together with the first metal pattern 41, and the first active layer 3 is not conductivized by ion injection, and is conductivized by dry etching, i.e., after etching the first sub-insulation layer 51, the surface of the second portion 32 is bombarded with a plasma of Ar or He, so as to change the properties of the second portion 32 of the first active layer 3 from a semiconductor to a conductor, with the advantage of reducing one-step ion injection process and simplifying the fabrication process of the thin film transistor.

In possible embodiments, as shown in conjunction with FIG. 1, FIG. 2A-FIG. 2G, FIG. 3A-FIG. 3B, FIG. 4, FIG. 5, FIG. 6, FIG. 7A-FIG. 7B, FIG. 8, and FIG. 9, the first insulation layer 2 includes: a first buffer layer; and a depth of the first concave portion 21 in a direction perpendicular to the base substrate 1 is the same as a thickness of the first buffer layer in the direction perpendicular to the base substrate 1. That is, the first concave portion 21 is a through hole penetrating through the first insulation layer 2.

Based on the same inventive concept, embodiments of the present disclosure also provide a display substrate. In possible embodiments, as shown in conjunction with FIG. 1, FIG. 2A-FIG. 2G, FIG. 3A-FIG. 3B, FIG. 4, FIG. 5, FIG. 6, FIG. 7A-FIG. 7B, FIG. 8, and FIG. 9, the display substrate has a display area AA, and a non-display area BB at the periphery of the display area AA. The display area AA includes a first signal line 40, a second signal line 70, and at least one thin film transistor as provided in the above embodiments of the present disclosure.

Specifically, the first signal line 40 may be a gate line and the second signal line 70 may be a data line.

In possible embodiments, as shown in conjunction with FIG. 1, FIG. 2A-FIG. 2G, FIG. 3A-FIG. 3B, FIG. 4, FIG. 5, FIG. 6, FIG. 7A-FIG. 7B, FIG. 8, and FIG. 9, the display substrate further includes: a fourth insulation layer 104 on the side of the second insulation layer 5 facing away from the first active layer 3, and a pixel electrode 9 on the side of the fourth insulation layer 104 facing away from the second insulation layer 5. The fourth insulation layer 104 has a third through hole K3, and the pixel electrode 9 is electrically connected to the first electrode 6 via the third through hole K3.

In possible embodiments, as shown in conjunction with FIG. 1, FIG. 2A-FIG. 2G, FIG. 3A-FIG. 3B, FIG. 4, FIG. 5, FIG. 6, FIG. 7A-FIG. 7B, FIG. 8 and FIG. 9, a center of the orthographic projection of the third through hole K3 on the base substrate 1 is on the side of a center of the orthographic projection of the first through hole K1 on the base substrate 1 facing away from the first portion 31. The display substrate further includes: a lap electrode 90 between the fourth insulation layer 104 and the pixel electrode 9. The first electrode 6 is electrically connected to the lap electrode 90 via the third through hole K3. The lap electrode 90 is electrically connected to the pixel electrode 9. In embodiments of the present disclosure, a center of the orthographic projection of the third through hole K3 on the base substrate 1 is on the side of a center of the orthographic projection of the first through hole K1 on the base substrate 1 facing away from the first portion 31. The pixel electrode 9 is electrically connected to the first active layer 3 by a two-step etching process, compared to the process in which the pixel electrode 9 is directly electrically connected to the first active layer 3 via a through hole, the difficulty of etching is large. In the embodiments of the present disclosure, the pixel electrode 9 is electrically connected to the first active layer 3via two through holes is less difficult in the fabrication process and easy to realize.

Specifically, as shown in conjunction with FIG. 1, FIG. 2A-FIG. 2G, FIG. 3A-FIG. 3B, FIG. 4, FIG. 5, FIG. 6, FIG. 7A-FIG. 7B, FIG. 8 and FIG. 9, the first through hole K1 is overlapped with at least a portion of the first concave section 21; the first electrode 6 includes: a portion at the bottom of the first concave section 21, a portion that covers a side wall of the first concave section 21 and a side wall of the first through hole K1, and a portion that extends outwardly to the surface of the side of the second sub-insulation layer 52 facing away from the first sub-insulation layer 51; the lap electrode 90 includes: a portion at the bottom of the third through hole K3, a portion covering a side wall of the third through hole K3, and a portion extending outwardly to the surface of the side of the fourth insulation layer 104 facing away from the second sub-insulation layer 52; and the pixel electrode 9 covers at least the area where the third through hole K3 is and the peripheral area of the third through hole K3. The portion of the lap electrode 90 at the bottom of the third through hole K3 is lapped with the portion of the first electrode 6 that extends outwardly to the side surface of the second sub-insulation layer 52 facing away from the first sub-insulation layer 51, thereby realizing the electrical connection between the lap electrode 90 and the first electrode 6; the portion of the lap electrode 90 that extends outwardly to the side surface of the fourth insulation layer 104 facing away from the second sub-insulation layer 52 is lapped with the pixel electrode 9, realizing the electrical connection between the lap electrode 90 and the pixel electrode 9.

The specific pattern of the lap electrode 90 may be designed according to the needs. The orthographic projection on the base substrate 1 may be a triangle, a quadrilateral, a pentagon, a hexagon, a circle, an oval, or other irregular shapes. The specific pattern of the lap electrode 90 needs to satisfy that: on the one hand, a contact lap can be realized with the pixel electrode 9, and, on the other hand, after being laminated with the pixel electrode 9, the overall outer contour of the two covers the orthographic projection of the third through hole K3 and the first through hole K1 on the base substrate 1.

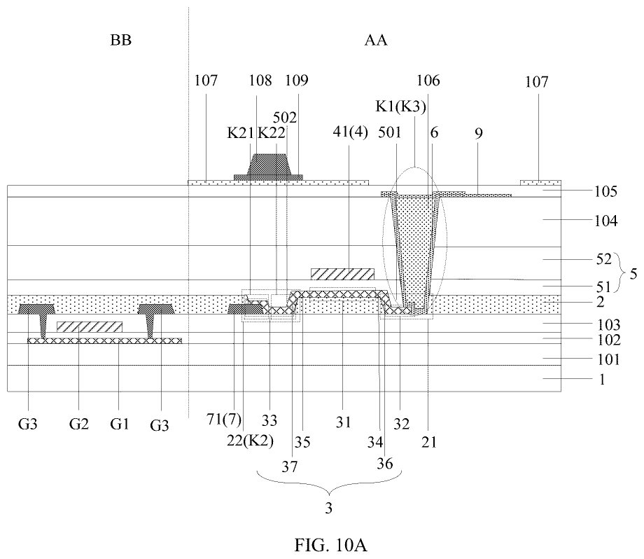

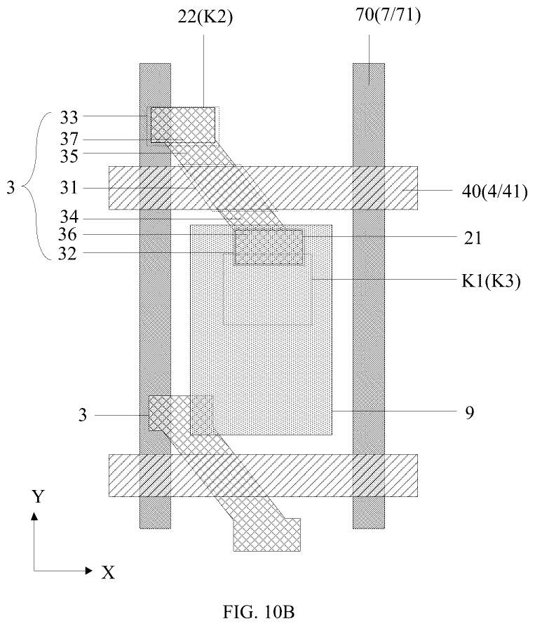

Specifically, the orthographic projection of the pixel electrode 9 on the base substrate 1 may cover the orthographic projection of the lap electrode 90 on the base substrate 1. Specifically, as shown in FIG. 2B or FIG. 10B, the shape of the orthographic projection of the pixel electrode 9 on the base substrate 1 can be rectangular.

In possible embodiments, as shown in conjunction with FIG. 1, FIG. 2A-FIG. 2G, FIG. 3A-FIG. 3B, FIG. 4, FIG. 5, FIG. 6, FIG. 7A-FIG. 7B, FIG. 8, and FIG. 9, the display substrate further includes: a third filling portion 106 filled within the third through hole K3. A segment difference between the surface of the third filling portion 106 facing away from the base substrate 11 and the surface of the fourth insulation layer 104 facing away from the base substrate 1 is less than 0.2 μm. Specifically, the fourth insulation layer 104 may be a second planarization layer PLN 2. In embodiments of the present disclosure, the display substrate further includes a third filling portion 106 filled within the third through hole K3, which may flatten the segment difference around the third through hole K3, and the segment difference between the surface of the third filling portion 106 facing away from the base substrate 11 and the surface of the fourth insulation layer 104 facing away from the base substrate 1 is less than 0.2 μm, which may avoid the liquid crystal orientation abnormality when performing the box-pairing process if the segment difference is greater than 0.2 μm, and avoid the light leakage problem caused by the excessive segment difference around the third through hole K3.

Specifically, the fourth insulation layer 104 may be a first planarization layer PLN1, and since this layer is usually thicker and light leakage occurs when the through hole is provided, the conventional design sets its through hole at a location where the shading metal wiring is to shade the light leakage. In the embodiments of the present disclosure, the third through hole K3 of the fourth insulation layer 104 is in the pixel opening area, which can be realized to increase the effective area of the pixel electrode 9, improve the liquid crystal efficiency, and be filled in by the third filling portion 106 to ensure that there is no light leakage caused by the segment difference.

In possible embodiments, referring to FIGS. 10A and 10B, the center of the orthographic projection of the third through hole K3 on the base substrate 1 coincides with the center of the orthographic projection of the first through hole K1 on the base substrate 1. The first electrode is electrically connected to the pixel electrode via the first through hole K1 and the third through hole K3. In the embodiments of the present disclosure, the center of the orthographic projection of the third through hole K3 on the base substrate 1 coincides with the center of the orthographic projection of the first through hole K1 on the base substrate 1. The pixel area adopts a deep set of through holes process, which allows the fourth insulation layer 104 and the second sub-insulation layer 52 to be used in a single etching method, saves the two mask processes when patterning the second sub-insulation layer 52 and the lapped electrode 90, and at the same time reduces one through hole of the pixel opening area, thereby improving the contrast of the display panel.

In the embodiments of the present disclosure, the first through hole K1 and/or the third through hole K3 electrically connecting the pixel electrode 9 to the first active layer 3 is/are in the pixel opening area, compared to that the first through hole K1 and/or the third through hole K3 electrically connecting the pixel electrode 9 to the first active layer 3 are at a position where the wiring of the non-pixel opening area is located, resulting in a portion of the area in the pixel electrode being used for conducting the electrical connection to the first active layer and a portion of the area being used for display, and the area of the conducting electrical connection being outside the pixel opening area, which cannot be used for display, making the effective area of the pixel electrode 9 smaller, whereas in the embodiments of the present disclosure, the first through hole K1 and/or the third through hole K3 electrically connecting the pixel electrode 9 to the first active layer 3 is/are in the pixel opening area, and the pixel electrode 9 is used for display while electrically connecting with the first active layer 3, increasing the effective area of the pixel electrode 9, improving the liquid crystal efficiency (the ability of the liquid crystal to deflect the linearly polarized light), and improving the light transmission rate of the display substrate.

Specifically, the pixel opening area can be understood as the area in the display substrate where the sub-pixels are used to perform the display. Specifically, the display panel may have a black matrix, and the black matrix may have a black matrix opening; an orthographic projection of the pixel opening area on the base substrate 1 may coincide with an orthographic projection of the black matrix opening on the base substrate 1.

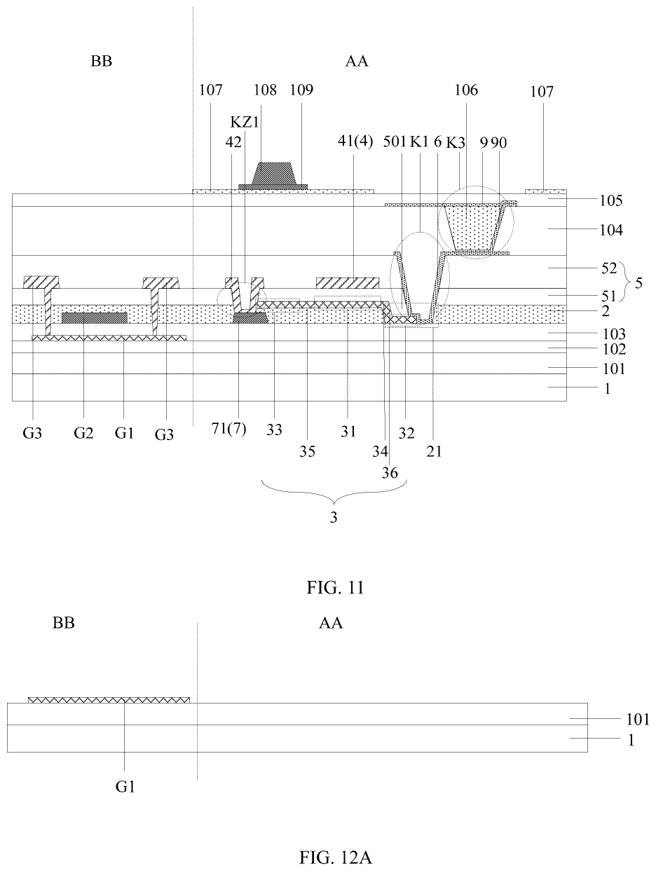

In possible embodiments, as shown in FIG. 1, FIG. 2A-FIG. 2G, FIG. 3A-FIG. 3B, FIG. 4, FIG. 5, FIG. 6, FIG. 7A-FIG. 7B, FIG. 8, FIG. 9, FIG. 10A-FIG. 10B, and FIG. 11, the orthographic projection of the pixel electrode 9 on the base substrate covers the orthographic projection(s) of the third through hole K3 and the first through hole K1 on the base substrate 1. Since there is a lap electrode 90 distributed in the third through hole K3 and a first electrode 6 distributed in the first through hole K1, the lap electrode in the through hole can form an electric field with an electrode layer (e.g., a common electrode layer) above the pixel electrode 9 as well, which may further interfere with the normal electric field formed between the pixel electrode 9 and the common electrode layer, which may further affect the normal deflection loaded on the liquid crystals, in the embodiments of the present disclosure, the pixel electrode 9 covers the orthographic projection(s) of the third through hole K3 and the first through hole K1 on the base substrate 1, the electric field in the through hole can be shielded to stabilize the electric field.

In possible embodiments, in conjunction with FIG. 2B, the first concave portion 21 has an overlapping portion 210 with the orthographic projection of the first through hole K1, the overlapping portion 210 is on the side of the second portion 32 facing away from the first signal line 40, and a distance c between the overlapping portion 210 and the first signal line 40 is greater than 0.75 μm, preventing the first electrode 6 at the first through hole K1 and the first metal pattern 41 from short-circuiting due to the fluctuation of the process.

In possible embodiments, as shown in conjunction with FIG. 2A-FIG. 10B, the display substrate further includes a gate drive circuit in the non-display area; a gate drive circuit board includes: a second active layer G1, a drive gate electrode G2 on the side of the second active layer G1 facing away from the base substrate 1, and a drive source-drain electrode G3 on the side of the drive gate electrode G2 facing away from the second active layer G1.

In possible embodiments, as shown in conjunction with FIG. 2A-FIG. 10B, the drive source-drain electrode G3 is in the second metal layer 7. In the embodiments of the present disclosure, the drive source-drain electrode G3 is in the second metal layer 7, which allows the drive source-drain electrode G3 of the non-display area BB to be formed while the second metal pattern 71 of the display area AA is formed, which can simplify the fabrication process of the display substrate.

In possible embodiments, as shown in conjunction with FIG. 6, the drive gate electrode G2 is in the third metal layer 8. In the embodiments of the present disclosure, the drive gate electrode G2 is in the third metal layer 8, and the drive gate electrode G2 of the non-displayed area BB can be formed while the second adapter electrode 82 of the display area AA is formed, which can simplify the fabrication process of the display substrate.

In possible embodiments, as shown in conjunction with FIG. 11, the drive source-drain electrode G3 is in the first metal layer 4; the drive gate electrode is in the second metal layer. In the embodiments of the present disclosure, the gate drive circuit of the non-display area BB and the metal layer of the display area AA are fully shared to reduce the number of masks.

In possible embodiments, the material of the first active layer 3 includes: rare earth element-doped indium-zinc oxide, or rare earth element-doped indium-gallium-zinc oxide. The rare earth element-doped indium-zinc oxide, or the rare earth element-doped indium-gallium-zinc oxide is a light-resistant metal oxide, and in the embodiments of the present disclosure, the material of the first active layer 3 is the rare earth element-doped indium-zinc oxide, or the rare earth element-doped indium-gallium-zinc oxide, and the first active layer 3 can have stable performance even when exposed to light, which can be used to avoid the need to set up a shielding layer in the pixel opening area and can further enhance the aperture ratio of the display substrate.

In possible embodiments, the material of the second active layer G1 includes: polysilicon. In the embodiments of the present disclosure, the first active layer 3 of the thin-film transistor in the display area may adopt an oxide active layer, and the driver transistor in the non-display area may adopt a polysilicon active layer, and the oxide thin-film transistor has an advantage such as low leakage current, and the low-temperature polycrystalline silicon thin-film transistor has an advantage such as high mobility, fast charging, and so on, and the low-temperature polycrystalline silicon thin-film transistor and the oxide thin-film transistor are integrated in a display substrate to form a low-temperature polycrystalline oxide display panel, utilizing the advantages of both, can achieve high resolution (Pixel Per Inch, PPI) , low-frequency driving, can reduce power consumption, and can improve display quality.

In possible embodiments, the material of the second active layer G1 includes: rare earth element-doped indium-zinc oxide, or rare earth element-doped indium-gallium-zinc oxide.

In possible embodiments, the material of the second active layer G1 is different from the material of the first active layer 3.

In possible embodiments, the first active layer 3 may be a diagonal non-linear pattern, specifically, as shown in conjunction with FIG. 2B, the second portion 32 and the third portion 33 both extend in the second direction Y, and the extension line of the second portion 32 does not overlap with the extension line of the third portion 33; an acute angle β is formed between at least a portion of the third portion 33 and the first signal line 40, and the acute angle β is facing a side of the electrically connected second signal line 70.

In possible embodiments, as shown in conjunction with FIG. 2B, the region in the first active layer 3 for lapping with the pixel electrode 9 may be taken as the first portion 31, and the region for lapping with the second signal line 70 is taken as the third portion 33. In possible embodiments, as shown in conjunction with FIG. 2B, the first portion 31 includes a diagonally extending portion, the diagonally extending portion overlaps the first signal line 40 to form a channel area.

In possible embodiments, as shown in conjunction with FIG. 2G, the first active layer 3 may be a diagonal pattern extending along a third direction Z, the second signal line 70 (data lines) may be a bent structure in the second direction Y, and pixel electrodes are provided in a region between two adjacent second signal lines 70 and a region between two adjacent first signal lines 40 (gate lines); a region in which the first active layer 3 overlaps the first signal line 40 (gate lines) serves as the first portion 31, the portion of the first active layer 3 electrically connected to the pixel electrode serves as the second portion 32, and the portion of the first active layer 3 electrically connected to the second signal line 70 (data lines) serves as the third portion 33.

In possible embodiments, as shown in conjunction with FIG. 2A-FIG. 11, the display substrate further includes: a common electrode 107 on the side of the pixel electrode 5 facing away from the base substrate 1; the common electrode 107 includes: a first common electrode portion extending along a first direction X, and a second common electrode portion extending along a second direction Y; an orthographic projection of the first common electrode portion on the base substrate 1 covers an orthographic projection of the first signal line 40 on the base substrate 1, and an orthographic projection of the second common electrode portion on the base substrate 1 covers an orthographic projection of the second signal line 70 on the base substrate 1; and an orthographic projection of the third through hole K3 on the base substrate 1 is within an orthographic projection of a cross region of the first common electrode portion and the second common electrode portion on the base substrate 1. In possible embodiments, an orthographic projection of the first through hole K1 on the base substrate 1 is within an orthographic projection of a cross region of the first common electrode portion and the second common electrode portion on the base substrate 1.

In possible embodiments, as shown in conjunction with FIGS. 2A-11 , the display substrate further includes: a first light-shielding layer 109 on the side of the common electrode 107 facing away from the pixel electrode 9 and in direct contact with the common electrode 107, and a spacer 108 on the side of the first light-shielding layer 109 facing away from the pixel electrode layer 6. An orthographic projection of the common electrode 107 on the base substrate 1 covers the orthographic projection of the first light-shielding layer 109 on the base substrate 1. A line width of the first light-shielding layer 109 is smaller than a line width of the common electrode 107; an orthographic projection of the first light-shielding layer 109 on the base substrate 1 covers an orthographic projection of the spacer 108 on the base substrate 1, and a line width of the spacer 108 is smaller than a line width of the first light-shielding layer 109.

Specifically, the first light-shielding layer 109 may be made of a blackened metal material, and the spacer 108 may be made of molybdenum or aluminum (i.e., a material that may be wet etched), and the first light-shielding layer 109 and the spacer 108 may be formed by a signal mask patterning process, using wet etching plus dry etching, by using the difference in the etching bias (bias) between the spacer 108 and the first light-shielding layer 109 to make the first light-shielding layer 109 and the spacer 108 form a step shape.

Specifically, the material of the first light-shielding layer 109 may also include any one or more of: titanium (Ti), chromium (Cr), cobalt (Co), nickel (Ni), copper (Cu), hafnium (Hf), tantalum (Ta), tungsten (W), bismuth (Bi), silver (Ag), or compounds thereof.

Specifically, the thickness of the first light-shielding layer 109 may be 30 nm ^{~}80 nm, and the thickness of the spacer 108 may be 0.4 μm ^{~}1 μm. Wherein the first light-shielding layer 109 may be used to shield the first signal line 40 and the second signal line 70 on the one hand, and on the other hand, the resistance of the common electrode 107 may be reduced.

In possible embodiments, the orthographic projection of the first light-shielding layer 109 on the base substrate 1 covers the orthographic projection of the second signal line 70 on the base substrate 1, and covers the orthographic projection of the first signal line 40 on the base substrate 1; and the orthographic projection of the spacer 108 on the base substrate 1 covers the orthographic projection of the second signal line 70 on the base substrate 11, and covers the orthographic projection of the first signal line 40 on the base substrate 1.

Specifically, the shape of the first light-shielding layer 109 and the shape of the spacer 108 may be similar to the shape of the pattern of the common electrode 107, i.e., the first light-shielding layer 109 may include a first light-shielding portion extending along a first direction X, and a second light-shielding portion extending along a second direction Y, and the first light-shielding portion and the second light-shielding portion are intersected to form a mesh structure; the spacer 108 may include a first spacer portion extending along the first direction X, and a second spacer portion extending along the second direction Y, the first spacer portion and the second spacer portion are intersected to form a mesh structure; the spacer 108 of the mesh structure can be designed with a narrower line width, which is conducive to increasing the aperture ratio of the display substrate.

Specifically, as shown in conjunction with FIG. 2A, the display substrate further includes at least one of the following:
a first buffer layer 101 between the base substrate 1 and the second active layer G1;
a first gate insulation layer 102 between the second active layer G1 and the drive gate electrode G2;
a passivation layer 105 between the pixel electrode 9 and the common electrode 107.

Specifically, the first insulation layer 2 may be a second buffer layer; the first sub-insulation layer 51 may be a second gate insulation layer; the second sub-insulation layer 52 may be a second interlayer dielectric layer; the third insulation layer 103 may be a first interlayer dielectric layer; and the fourth insulation layer 104 may be a first planarization layer.

In some embodiments, at least one of the first buffer layer, the second buffer layer, the first interlayer dielectric layer, the second interlayer dielectric layer, the first gate insulation layer, the second gate insulation layer, the first planarization layer, and the second planarization layer may be an inorganic insulation layer, which may be any one or more of silicon oxide (SiOx), silicon nitride (SiNx), and silicon oxynitride (SiON), and may be a single layer, multi-layer or composite layer. At least one of the first metal layer, the second metal layer, and the third metal layer may be a metal material, such as any one or more of aluminum (Al), titanium (Ti), chromium (Cr), cobalt (Co), nickel (Ni), copper (Cu), molybdenum (Mo), hafnium (Hf), tantalum (Ta), tungsten (W), bismuth (Bi), and silver (Ag), or alloys of the above mentioned metals such as an aluminum-neodymium alloy (AINd) or molybdenum-niobium (MoNb) alloys, which may have a monolayer structure, or a multilayer composite structure, such as Ti/Al/Ti.

For a clearer understanding of the display substrate provided by embodiments of the present disclosure, the following is described in further detail in conjunction with FIG. 12A-FIG. 12I as follows.

Step 1, a first buffer layer 101 is deposited on the base substrate 1. The material of the first buffer layer 101 may include: SiN and/or SiO2 and/or aSi, and the thickness may be 200 nm^{~}500 nm, and polycrystalline silicon (poly-Si) is crystallized to form polycrystalline silicon (poly-Si), i.e., Excimer Laser Annealing (ELA), and then is patterning, as shown in FIG. 12A below.

Step 2, a first gate insulation layer 102 is formed. The material of the first gate insulation layer 102 may include: SiO2, and the thickness may be 100 nm^{~}150 nm; and then the drive gate electrode G2 of the Low Temperature Poly-Silicon (LTPS) thin film transistor is deposited, and the material of the drive gate electrode G2 may include: Mo, Al, etc.; thereafter, the shape of the drive gate electrode G2 is formed by photolithography and etching, and a first interlayer dielectric layer 103 continues to be completed, as shown in FIG. 12B below.

Step 3, the first interlayer dielectric layer 103 is through holed and a second metal layer 7 is deposited and patterned to form a drive source-drain electrode G3 and a second metal pattern 71; the material of the second metal layer 7 is selected from a metal such as Mo, Al, Ti, etc., and then is patterned; and then a second buffer layer is deposited, i.e., the first insulation layer 2, and the material of the first insulation layer 2 includes: a SiO2 or a SiN/SiO2 are laminated, as shown in FIG. 12C below.

Step 4, the first insulation layer 2 is patterned and etched via a through hole, with one through hole (such as the second concave portion 22) lapping on the second metal pattern 71. Using a half-lap manner can reduce the size of the through hole, and the metal oxide inside the through hole will automatically compensate, increasing the lapping area and improving the lapping resistance problem; another through hole (such as the first concave portion 21) is in the pixel opening area, as shown in FIGS. 12D and 12E.

Step 5, high mobility metal oxide semiconductor layer HMOS deposition is performed, and the material is selected from rare earth doped IGZO or ITZO or other materials, and patterning is performed as a first active layer 3; then a first sub-gate insulation layer 51 is deposited, i.e., a second gate insulation layer, and the material of the first sub-gate insulation layer 51 includes SiO2; and a first metal layer 4 is deposited, and patterning is performed, as a first metal pattern 41 (e.g., the gate electrode); the first active layer 3 spans the second metal pattern 71, which is an under-lap; combined with FIG. 2C, at the same time, after completing the first metal pattern 41, an ion injection conductorization process is performed, and since the region of the first active layer 3 to be conductivated and the semiconductor region are separated from the upper and lower portions of the first active layer 3, so that the semiconductor region is less affected by conductorization and the lateral diffusion is reduced, which is conducive to improving the short-channel characteristics deterioration problem, and at the same time channel oblique design is performed in the direction parallel to the base substrate 1, bending design is performed in the direction perpendicular to the base substrate 1, which increase the length of the effective channel to a certain extent, and improve the device characteristics, as shown in FIG. 12F and FIG. 12G; specifically, the width b1 of the un-conducted region in the second direction Y and the width b2 of the first signal line 40 in the second direction Y, satisfy the following: b2×30%<b1<b2×75%, where b1=a1+a2.

Step 6, the second sub-insulation layer 52 is deposited and etched to form the first through hole K1; the etching of the deep first through hole K1 also has an impact on the device characteristics, and a straddle structure is used, wherein the dry-etched by-products are isolated by the first filling portion 501 of the first sub-gate insulation layer 51, which can block diffusion, and the contacting of the exposed portion of the first active layer 3 laterally diffuses across the lateral transition area (i.e., the first connection portion 34), which is conducive to enhancing the short channel characteristics; and further forming the pixel area transfer layer ITO, i.e., the first electrode 6, as shown in FIG. 12H.

Step 7, continuing to complete the back-end process, as shown in FIG. 12I.

Based on the same inventive concept, embodiments of the present disclosure also provide a display device, including the display substrate provided in the embodiments of the present disclosure.

Although preferred embodiments of the present disclosure have been described, those skilled in the art may make additional changes and modifications to these embodiments once the basic inventive concept is known. Therefore, the appended claims are intended to be construed as including the preferred embodiments as well as all changes and modifications falling within the scope of the present disclosure.

Obviously, a person skilled in the art may make various changes and variations to the embodiments of the present disclosure without departing from the spirit and scope of the embodiments of the present disclosure. Thus, if such modifications and variations of the embodiments of the present disclosure fall within the scope of the claims of the present disclosure and their technical equivalents, the present disclosure is intended to encompass such modifications and variations.

1. A thin film transistor, comprising:
a base substrate;
a first insulation layer, on a side of the base substrate and being provided with a first concave portion;
a first active layer, on a side of the first insulation layer facing away from the base substrate and comprising: a first portion, and a second portion on a side of the first portion; wherein the second portion is in the first concave portion;
a first metal layer, on a same side of the base substrate as the first active layer and comprising a first metal pattern; wherein an orthographic projection of the first portion on the base substrate has an overlapping region with an orthographic projection of the first metal pattern on the base substrate.

2. The thin film transistor according to claim 1, further comprising:
a second insulation layer on a side of the first active layer facing away from the first insulation layer; and
a first electrode on a side of the second insulation layer facing away from the first active layer;
wherein the second insulation layer is provided with a first through hole, the first electrode is electrically connected to the second portion via the first through hole.

3. The thin film transistor according to claim 2, wherein the first active layer further comprises: a first connection portion between the first portion and the second portion, the first connection portion covers a portion of a side wall of the first concave portion;
the second insulation layer comprises a first filling portion, an orthographic projection of the first filling portion on the base substrate has an overlapping region with an orthographic projection of the first concave portion on the base substrate, and the first filling portion covers the first connection portion.

4. The thin film transistor according to claim 1, wherein the first insulation layer further comprises a second concave portion;
the first active layer further comprises a third portion on an other side of the first portion; at least a portion of the third portion is in the second concave portion.

5. The thin film transistor according to claim 3, wherein the first active layer further comprises a second connection portion between the first portion and the third portion, the second connection portion covers a portion of a side wall of the second concave portion;
the second insulation layer comprises a second filling portion, an orthographic projection of the second filling portion on the base substrate has an overlapping region with an orthographic projection of the second concave portion on the base substrate, and the second filling portion covers the second connection portion;
wherein the first active layer further comprises a fourth portion between the first portion and the first connection portion, and a fifth portion between the first portion and the second connection portion;
an orthographic projection of the fourth portion on the base substrate does not overlap the orthographic projection of the first metal pattern on the base substrate, and an orthographic projection of the fifth portion on the base substrate does not overlap the orthographic projection of the first metal pattern on the base substrate.

6. (canceled)

7. The thin film transistor according to claim 1, wherein the first insulation layer further comprises a second concave portion;
at least a portion of the first portion is in the second concave portion.

8. The thin film transistor according to claim 3, further comprising:
a second metal layer between the first insulation layer and the base substrate;
wherein the second concave portion is a second through hole penetrating through the first insulation layer;
the second metal layer comprises a second metal pattern; at least a portion of the second metal pattern is in the second through hole, a portion of the third portion in the second through hole is electrically connected to the second metal pattern.

9. The thin film transistor according to claim 8, wherein the second through hole comprises: a first sub-through hole portion, and a second sub-through hole portion;
an orthographic projection of the first sub-through hole portion on the base substrate overlaps an orthographic projection of the second metal pattern on the base substrate, and
an orthographic projection of the second sub-through hole portion on the base substrate is on a side, facing the orthographic projection of the first portion on the base substrate, of the orthographic projection of the first sub-through hole portion on the base substrate; or
an orthographic projection of the second sub-through hole portion on the base substrate is on a side, facing away from the orthographic projection of the first portion on the base substrate, of the orthographic projection of the first sub-through hole portion on the base substrate.

10. (canceled)

11. The thin film transistor according to claim 1, further comprising:
a second metal layer between the first insulation layer and the base substrate;
wherein the second metal layer comprises a second metal pattern; the first active layer further comprises: a third portion on an other side of the first portion;
the first metal layer further comprises a first adapter electrode; the third portion is electrically connected to the second metal pattern via the first adapter electrode;
wherein an orthographic projection of the second metal pattern on the base substrate overlaps at least a portion of the orthographic projection of the first metal pattern on the base substrate.

12. (canceled)

13. The thin film transistor according to claim 1, further comprising:
a second metal layer between the first insulation layer and the base substrate; and
a third metal layer between the second metal layer and the base substrate;
wherein the first active layer further comprises: a third portion on an other side of the first portion;
the second metal layer comprises a second metal pattern; the third metal layer comprises a second adapter electrode; the third portion is electrically connected to the second metal pattern via the second adapter electrode.

14. The thin film transistor according to claim 13, wherein at least a portion of an orthographic projection of the second metal pattern on the base substrate is on a side of an orthographic projection of the second adapter electrode on the base substrate facing away from the first portion; or
wherein at least a portion of an orthographic projection of the second metal pattern on the base substrate is on a side of an orthographic projection of the second adapter electrode on the base substrate close to the first portion.

15. (canceled)

16. The thin film transistor according to claim 1, wherein the first insulation layer further comprises a second concave portion; the thin film transistor further comprises a second metal layer between the first insulation layer and the base substrate; the second concave portion is a second through hole penetrating through the first insulation layer;
the second metal layer comprises a second metal pattern, at least a portion of the second metal pattern is in the second through hole;
at least a portion of the first portion is in the second through hole, the portion of the first portion in the second through hole is electrically connected to the second metal pattern.

17. The thin film transistor according to claim 2, wherein the second insulation layer comprises: a first sub-insulation layer, and a second sub-insulation layer on a side of the first sub-insulation layer facing away from the first active layer;
the first metal layer is on a side of the first active layer facing away from the base substrate.

18. The thin film transistor according to claim 17, wherein an orthographic projection of the first sub-insulation layer on the base substrate covers the orthographic projection of the first portion on the base substrate; the first sub-insulation layer comprises a first filling portion; and/or
wherein an orthographic projection of the first sub-insulation layer on the base substrate covers at least a portion of the orthographic projection of the first portion on the base substrate, and the orthographic projection of the first sub-insulation layer on the base substrate does not overlap an orthographic projection of the second portion on the base substrate and does not overlap an orthographic projection of a third portion on the base substrate; the second sub-insulation layer comprises the first filling portion.

19. (canceled)

20. The thin film transistor according to claim 1, wherein the first concave portion has a depth in a direction perpendicular to the base substrate, and the depth is the same as a thickness of the first insulation layer in the direction perpendicular to the base substrate.

21. The thin film transistor according to claim 2, wherein a depth el of the first through hole in a direction perpendicular to the base substrate satisfies a following relationship:
e2<e1≤e2+e3, wherein e2 indicates a thickness of the second insulation layer in the direction perpendicular to the base substrate, and e3 indicates a thickness of the first insulation layer in the direction perpendicular to the base substrate.

22. A display substrate, comprising a display area, and a non-display area at a periphery of the display area, wherein a first signal line, a second signal line, and at least one thin-film transistor are provided in the display area, wherein the thin-film transistor comprises:
a base substrate;
a first insulation layer, on a side of the base substrate and being provided with a first concave portion;
a first active layer, on a side of the first insulation layer facing away from the base substrate and comprising: a first portion, and a second portion on a side of the first portion; wherein the second portion is in the first concave portion;
a first metal layer, on a same side of the base substrate as the first active layer and comprising a first metal pattern; wherein an orthographic projection of the first portion on the base substrate has an overlapping region with an orthographic projection of the first metal pattern on the base substrate.

23. The display substrate according to claim 22, wherein the display substrate further comprises:
a fourth insulation layer on a side of a second insulation layer facing away from the first active layer; and
a pixel electrode on a side of the fourth insulation layer facing away from the second insulation layer;
wherein the fourth insulation layer is provided with a third through hole, the pixel electrode is electrically connected to the first electrode via the third through hole;
wherein the display substrate further comprises:
a gate drive circuit in the non-display area;
wherein the gate drive circuit comprises: a second active layer, a drive gate electrode on a side of the second active layer facing away from the base substrate, and a drive source-drain electrode on a side of the drive gate electrode facing away from the second active layer;
wherein the drive source-drain electrode is in a second metal layer;
wherein the drive gate electrode is in a third metal layer;
wherein the drive source-drain electrode is in the first metal layer; and the drive gate electrode is in the second metal layer.

24-25. (canceled)

26. The display substrate according to claim 22, wherein the first concave portion has an overlapping portion with an orthographic projection of the first through hole, the overlapping portion is on a side of the second portion facing away from the first signal line, a distance between the overlapping portion and the first signal line is greater than 0.75 μm.

27-30. (canceled)

31. A display device, comprising a display substrate, wherein the display substrate comprises a display area, and a non-display area at a periphery of the display area, wherein a first signal line, a second signal line, and at least one thin-film transistor are provided in the display area, wherein the thin-film transistor comprises:
a base substrate;
a first insulation layer, on a side of the base substrate and being provided with a first concave portion;
a first active layer, on a side of the first insulation layer facing away from the base substrate and comprising: a first portion, and a second portion on a side of the first portion; wherein the second portion is in the first concave portion;
a first metal layer, on a same side of the base substrate as the first active layer and comprising a first metal pattern; wherein an orthographic projection of the first portion on the base substrate has an overlapping region with an orthographic projection of the first metal pattern on the base substrate.
